(19) United States
(12) Patent Application Publication
(10) Pub. No.: US 2026/0271503 A1
(43) Pub. Date: Sep. 10, 2026

(54) ORGANIC ELECTROLUMINESCENT DEVICE

(71) Applicant: The Trustees of Princeton University, Princeton, NJ (US)

(72) Inventors: Jesse Alexander Wisch, Princeton, NJ (US); Xiao Liu, San Jose, CA (US); Barry Patrick Rand, Princeton, NJ (US)

(21) Appl. No.: 19/165,468

(22) PCT Filed: Mar. 15, 2024
(86) PCT No.: PCT/US2024/020155

§ 371 Date: Sep. 15, 2025

Related U.S. Application Data
(60) Provisional application No. 63/452,368, filed on Mar. 15, 2023.

(51) Int. Cl. H10K 50/12; H10K 50/14; H10K 85/60

(52) U.S. Cl. CPC H10K 50/121; H10K 50/14; H10K 85/626

(57) ABSTRACT

An organic optoelectronic device comprises a first electrode, a first charge transport layer positioned over the first electrode, a first emissive layer positioned over the first charge transport layer, a second charge transport layer positioned over the first emissive layer, a second electrode positioned over the second charge transport layer, and a top organic emissive layer positioned over the second electrode, configured to convert surface plasmon polaritons on a surface of the second electrode to light. A white emitting organic optoelectronic device and a method for transferring energy to acceptor molecules are also disclosed.

### CROSS-REFERENCE TO RELATED APPLICATIONS

This application claims priority to U.S. Provisional Application No. 63/452,368, filed on Mar. 15, 2023, incorporated herein by reference in its entirety.

### STATEMENT REGARDING FEDERALLY SPONSORED RESEARCH OR DEVELOPMENT

This invention was made with government support under Grant No. DESC0019370 awarded by the Department of Energy. The government has certain rights in the invention.

### BACKGROUND OF THE INVENTION

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety. One application for phosphorescent emissive molecules is a full color display. Industry standards for such a display call for pixels adapted to emit particular colors, referred to as “saturated” colors. In particular, these standards call for saturated red, green, and blue pixels. Alternatively, the OLED can be designed to emit white light. In conventional liquid crystal displays emission from a white backlight is filtered using absorption filters to produce red, green and blue emission. The same technique can also be used with OLEDs. The white OLED can be either a single EML device or a stack structure. Color may be measured using CIE coordinates, which are well known to the art.

One example of a green emissive molecule is tris(2-phenylpyridine) iridium, denoted Ir(ppy)₃, which has the following structure:

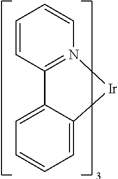

In this, and later figures herein, we depict the dative bond from nitrogen to metal (here, Ir) as a straight line.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, on a conventional energy level diagram, with the vacuum level at the top, a “shallower” energy level appears higher, or closer to the top, of such a diagram than a “deeper” energy level, which appears lower, or closer to the bottom.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

Layers, materials, regions, and devices may be described herein in reference to the color of light they emit. In general, as used herein, an emissive region that is described as producing a specific color of light may include one or more emissive layers disposed over each other in a stack.

As used herein, a “red” layer, material, region, or device refers to one that emits light in the range of about 570-700 nm or having a highest peak in its emission spectrum in that region. Similarly, a “green” layer, material, region, or device refers to one that emits or has an emission spectrum with a peak wavelength in the range of about 500-600 nm; a “blue” layer, material, or device refers to one that emits or has an emission spectrum with a peak wavelength in the range of about 400-500 nm; a “yellow” layer, material, region, or device refers to one that has an emission spectrum with a peak wavelength in the range of about 540-600 nm; a “cyan” layer, material, or device refers to one that emits or has an emission spectrum with a peak wavelength in the range of about 490-520 nm; and an “orange” layer, material, or device refers to one that emits or has an emission spectrum with a peak wavelength in the range of about 570-620 nm. In some arrangements, separate regions, layers, materials, regions, or devices may provide separate “deep blue” and a “light blue” light. As used herein, in arrangements that provide separate “light blue” and “deep blue”, the “deep blue” component refers to one having a peak emission wavelength that is at least about 4 nm less than the peak emission wavelength of the “light blue” component. Typically, a “light blue” component has a peak emission wavelength in the range of about 465-500 nm, and a “deep blue” or “dark blue” component has a peak emission wavelength in the range of about 400-470 nm, though these ranges may vary for some configurations. A “light green” component has a peak emission wavelength in the range of about 520-560 nm, and a “deep green” or “dark green” component has a peak emission wavelength in the range of about 500-520 nm, though these ranges may vary for some configurations. A near infrared (“NIR”) component has a peak emission wavelength in the range of about 700-1800 nm. Similarly, a color altering layer refers to a layer that converts or modifies another color of light to light having a wavelength as specified for that color. For example, a “red” color filter refers to a filter that results in light having a wavelength in the range of about 580-700 nm. In general, there are two classes of color altering layers: color filters that modify a spectrum by removing unwanted wavelengths of light, and color changing layers that convert photons of higher energy to lower energy. A component “of a color” refers to a component that, when activated or used, produces or otherwise emits light having a particular color as previously described. For example, a “first emissive region of a first color” and a “second emissive region of a second color different than the first color” describes two emissive regions that, when activated within a device, emit two different colors as previously described.

As used herein, emissive materials, layers, and regions may be distinguished from one another and from other structures based upon the spectrum of light initially generated by the material, layer or region, as opposed to light eventually emitted by the same or a different structure. The initial light generation typically is the result of an energy level change resulting in emission of a photon. For example, an organic emissive material may initially generate blue light, which may be converted by a color filter, quantum dot or other structure to red, green, or yellow light, such that a complete emissive stack or sub-pixel emits the red, green, or yellow light. In this case the initial emissive material or layer may be referred to as a “blue” component, even though the sub-pixel is a “red”, “green”, or “yellow” component.

In some cases, it may be preferable to describe the color of a component such as an emissive region, sub-pixel, color altering layer, or the like, in terms of 1931 CIE coordinates. For example, a yellow emissive material may have multiple peak emission wavelengths, one in or near an edge of the “green” region, and one within or near an edge of the “red” region as previously described. Accordingly, as used herein, each color term also corresponds to a shape in the 1931 CIE coordinate color space. The shape in 1931 CIE color space is constructed by following the locus between two color points and any additional interior points. For example, interior shape parameters for red, green, blue, and yellow may be defined as shown below:

| Color | CIE Shape Parameters |
|---|---|
| Central Red | Locus: [0.6270, 0.3725]; [0.7347,0.2653]; |
| | Interior: [0.5086, 0.2657] |
| Central Green | Locus: [0.0326, 0.3530]; [0.3731, 0.6245]; |
| | Interior: [0.2268, 0.3321 |
| Central Blue | Locus: [0.1746, 0.0052]; [0.0326, 0.3530]; |
| | Interior: [0.2268, 0.3321] |
| Central Yellow | Locus: [0.373 l, 0.6245]; [0.6270, 0.3725]; |
| | Interior: [0.3 700, 0.4087]; [0.2886, 0.4572] |

More details on OLEDs, and the definitions described above, can be found in U.S. Pat. No. 7,279,704, which is incorporated herein by reference in its entirety.

Organic semiconductors (OSCs) have received considerable research interest in recent decades for applications including displays, lighting, and solar cells. While OSCs have relatively poor electronic properties (i.e., carrier mobility, morphological and molecular stability) when compared to inorganic semiconductors, their photophysical properties—including high luminescence quantum yields, high absorption coefficients, and synthetic tunability—give considerable merit to organic optoelectronic devices. The success of organic light-emitting diodes (OLEDs) (see C. W. Tang, et al., Appl. Phys. Lett., 1987; M. A. Baldo, et al., Nature, 1998; H. Uoyama, et al., Nature, 2012) has shown that the merits of OSCs are sufficient for commercial viability. Furthermore, the photophysical properties of organic dyes and chromophores have unlocked many solution-phase applications, such as photoredox catalyzed organic synthesis (see C. K. Prier, et al., Chem. Rev., 2013), visible-light catalyzed hydrogen evolution (J. Kosco, et al., Nat. Mater., 2020), triplet fusion upconversion catalysis (L. M. Campos, et al., Nature, 2019), and fluorescent probe bioimaging (T. Terai, et al., Pflugers Archiv—Eur. J. Phys., 2013).

For solution-phase applications, organic chromophores are typically excited with far-field light sources such as lamps and lasers. This requires that a photon emitted by the light source is appropriately ‘guided’ to the chromophore without parasitic absorption, reflection, or scattering. In addition, far-field photons from an excitation source can convolute signals emitted from a sample. In contrast to far-fields, where energy transfer processes are mediated by traveling photons, near-field energy transfer processes are mediated by localized virtual photons (see T. Forster, Annalen der physik, 1948). Near-field energy transfer to chromophores can have several advantages over far-field transfer. For example, a near-field is ‘invisible’ in the absence of an absorptive medium, and thus cannot convolute signals emitted from a sample. In addition, the non-traveling virtual photons that mediate energy transfer do not require ‘guidance’ as do far-field photons, because the near-field energy transfer process relies on an acceptor being located within the near-field.

However, in order to harvest the benefits of near-field energy transfer, a suitable medium to host near-fields is required. The near-field of surface plasmon polaritons (SPPs) can mediate energy transfer to chromophores; SPPs are quasiparticles that represent coupled photons and delocalized electrons, and can travel along metal/dielectric interfaces with a concomitant near-field decaying perpendicularly to the interface (see W. L. Barnes, et al., Nature, 2003). Previous work (P. Andrew, et al., Science, 2004) has shown that donor chromophores can couple to SPP modes in a metallic thin film, and this generated SPP near-field can excite acceptor chromophores.

Thus, there is a need in the art for an organic optoelectronic diode that achieves near-field energy transfer to molecules in solution via SPPs.

### SUMMARY OF THE INVENTION

In one aspect, an organic optoelectronic device comprises a first electrode, a first charge transport layer positioned over the first electrode, a first emissive layer positioned over the first charge transport layer, a second charge transport layer positioned over the first emissive layer, a second electrode positioned over the second charge transport layer, and a top organic emissive layer positioned over the second electrode, configured to convert surface plasmon polaritons on a surface of the second electrode to light.

In one embodiment, the top organic emissive layer comprises a solution-phase or solid state acceptor material. In one embodiment, the top organic emissive layer comprises an upconversion layer. In one embodiment, the top organic emissive layer comprises 2-methyl-9,10-bis(naphthalen-2-yl)anthracene (MADN). In one embodiment, the top organic emissive layer comprises a material selected from the group consisting of a phosphorescent emitter, delayed fluorescent emitter, and a non-delayed fluorescent emitter. In one embodiment, the first emissive layer comprises a material selected from the group consisting of a phosphorescent emitter, delayed fluorescent emitter, and a non-delayed fluorescent emitter. In one embodiment, the top organic emissive layer comprises a sensitizer and an acceptor.

In one embodiment, the first emissive layer comprises a sensitizer and an acceptor. In one embodiment, the first electrode is an anode and the second electrode is a cathode. In one embodiment, the first electrode is a cathode and the second electrode is an anode. In one embodiment, the first emissive layer comprises an emissive material selected from the group consisting of a green emissive layer, a blue emissive layer, a yellow emissive layer, a red emissive layer, and a near IR emissive layer. In one embodiment, the first emissive layer is a green emissive layer. In one embodiment, the first emissive layer comprises a metal compound having metal selected from the group consisting of Ir, Pt, Pd, Os, Cu, Ag, and Au. In one embodiment, the first emissive layer comprises Ir(ppy)₃. In one embodiment, the device further comprises a second emissive layer positioned between the first charge transport layer and the first emissive layer.

In one embodiment, the second emissive layer is a red emissive layer. In one embodiment, the second emissive layer has a thickness of less than 3 nm. In one embodiment, the first electrode comprises a high-conductivity metal. In one embodiment, the first emissive layer comprises a triplet-harvesting emissive dopant. In one embodiment, the first electrode is a transparent or semitransparent anode.

In one aspect, a white emitting organic optoelectronic device comprises a first electrode, a first charge transport layer positioned over the first electrode, a red emissive layer positioned over the first charge transport layer, a green emissive layer positioned over the first charge transport layer, a second charge transport layer positioned over the green emissive layer, a second electrode positioned over the second charge transport layer, and a blue upconversion layer positioned over the second electrode, configured to convert surface plasmon polaritons on a surface of the second electrode to blue light. In one embodiment, the green emissive layer is positioned over the red emissive layer. In one embodiment, the red emissive layer has a thickness of less than 3 nm. In one embodiment, the blue upconversion layer comprises a sensitizer layer and an annihilator layer.

In one embodiment, the device further comprises a power source configured to drive the white emitting organic optoelectronic device at a current density of at least 100 mA/cm². In one embodiment, the green emissive layer comprises Ir(ppy)₃.

In one embodiment, a consumer product comprising any device disclosed herein is selected from a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video walls comprising multiple displays tiled together, a theater or stadium screen, a light therapy device, or a sign.

In one aspect, a device comprises an emissive donor layer disposed between a first electrode and a first surface of a second electrode and an acceptor layer operably coupled to a second surface of the second electrode, the second surface being opposite the first surface. In one embodiment, the emissive donor layer is a phosphor-doped emissive layer. In one embodiment, the phosphor-doped emissive layer comprises 4,4′,4″-tris(carbazole-9-yl)triphenylamine (TCTA), bis[2-(4,6-difluorophenylpyridinato-C2,N](picolinato)iridium(III) (FIrPic), and 1,3,5-tri(m-pyridin-3-ylphenyl)benzene (TmPyPb).

In one embodiment, the device further comprises at least one electron injection layer (EIL) and/or hole injection layer (HIL) between the first electrode and the emissive donor layer. In one embodiment, the device includes an EIL and an HIL. In one embodiment, the HL comprises a poly(3,4-ethylenedioxythiophene) polystyrene sulfonate (PEDOT:PSS) layer and the EIL comprises a TCTA layer. In one embodiment, the EIL is disposed between the HIL and the emissive donor layer. In one embodiment, the device further comprises at least one electron transport layer (ETL) and/or hole transport layer (HTL) between the emissive donor layer and the second electrode.

In one embodiment, the ETL comprises a TmPyPb layer. In one embodiment, the device further comprises a dielectric spacer layer between the ETL and the second electrode. In one embodiment, the dielectric spacer layer has a refractive index nr, where n≤1.5 In one embodiment, the dielectric spacer comprises LiF. In one embodiment, the device further comprises a second dielectric layer between the second electrode and the acceptor layer. In one embodiment, the second dielectric layer has a refractive index n, where n≤1.5 In one embodiment, the second dielectric layer comprises LiF. In one embodiment, the second electrode is silver. In one embodiment, the acceptor layer comprises a solid-state acceptor with a bandwidth that overlaps an emission bandwidth of the emissive donor layer.

In one embodiment, the acceptor layer comprises a dye. In one embodiment, the dye is 4-(dicyanomethylene)-2-methyl-6-(4-dimethylaminostyryl)-4H-pyran (DCM). In one embodiment, the first electrode is an anode and the second electrode is a cathode. In one embodiment, the first electrode is a cathode and the second electrode is an anode.

In one aspect, a method for transferring energy to acceptor molecules comprises providing a device as disclosed herein, forming donor excitons in the emissive donor layer by passing an electrical current through the emissive donor layer, and allowing the donor excitons to generate travelling surface plasmon polaritons (SPPs) in the second electrode and allowing the near-field of the SPPs to excite acceptor molecules in the acceptor layer.

### BRIEF DESCRIPTION OF THE DRAWINGS

The foregoing purposes and features, as well as other purposes and features, will become apparent with reference to the description and accompanying figures below, which are included to provide an understanding of the invention and constitute a part of the specification, in which like numerals represent like elements, and in which:

FIG. 1 shows an organic light emitting device;

FIG. 2 shows an inverted organic light emitting device that does not have a separate electron transport layer;

FIG. 3A is a conceptual schematic of an exemplary PMET diode. Donor excitons form in the EML and generate traveling SPPs in the silver cathode. The near-field of these SPPs excites acceptor molecules;

FIG. 3C is an exemplary device stack of a PMET diode;

FIG. 4A and FIG. 4B are diagrams of device stacks as disclosed herein;

FIG. 5A is a diagram of an exemplary OLED disclosed herein;

FIG. 5B is a diagram of an exemplary OLED disclosed herein;

FIG. 6A is a diagram of an exemplary OLED and a corresponding graph of normalized luminance;

FIG. 6B is a diagram of an exemplary OLED and a corresponding graph of normalized luminance;

FIG. 7A is a graph of luminance as a function of different wavelengths;

FIG. 7B is a graph of luminance as a function of different wavelengths measured at different current densities;

FIG. 7C is a graph of upconversion efficiency as a function of current density;

FIG. 7D is a graph of upconversion efficiency as a function of power density;

FIG. 8 is a diagram of an exemplary OLED;

FIG. 9A is a graph of normalized luminance as a function of different wavelengths;

FIG. 9B is a graph of luminance as a function of current density for different device configurations;

FIG. 9C is a graph of EQE as a function of current density for different device configurations;

FIG. 10A and FIG. 10B are graphs of CIE coordinates for different devices at different current density;

FIG. 10C and FIG. 10D are graphs of CRI and CCT for different devices at different current densities;

FIG. 11A is a graph of TRPL decay curves for structure shown in the inset;

FIG. 11B is a graph of TE-EQE measurements of the PMET diode with a solid-state acceptor separated from the cathode by various thickness of a LiF spacer;

FIG. 12A is a graph of Molar absorptivity of DCM dye (red line) and EL of FIrPic (black line);

FIG. 12B is a top-emitting EL spectra of DCM-acceptor PMET diodes, with and without a glass spacer. The PL of a 5 μM DCM solution in MeCN is included for reference;

FIG. 12C is a top-emitting EQE vs. current density of target device (red circle) and three control devices;

FIG. 12D is a graph of calculated OpMr as a function of current density, from Equation 1;

FIG. 13A is a graph of PMET diode TE-EQE as a function of current density with various concentrations of TMB added to dye solution;

FIG. 13B is a set of Stern-Volmer plots of DCM emission from PMET diode (red diamond) and conventional far-field optical excitation (black square);

FIG. 13C shows PL spectra from photoexcited 13 mM DCM solution with various concentrations of TMB;

FIG. 14A is a graph of TRPL decay curves for structure shown in the inset;

FIG. 14B is a graph of raw steady-state PL spectra from device structures;

FIG. 15A-FIG. 15E are graphs of experimental data;

FIG. 16A-FIG. 16C are graphs of experimental data;

FIG. 17A and FIG. 17B are graphs of experimental data;

FIG. 18 is a simulated color plot of energy dissipation;

FIG. 19 is a simulated fraction of total power consumed by each section of a device; and

FIG. 20A and FIG. 20B are graphs of simulation data.

### DETAILED DESCRIPTION

It is to be understood that the figures and descriptions of the present invention have been simplified to illustrate elements that are relevant for a clear understanding of the present invention, while eliminating, for the purpose of clarity, many other elements found in related systems and methods. Those of ordinary skill in the art may recognize that other elements and/or steps are desirable and/or required in implementing the present invention. However, because such elements and steps are well known in the art, and because they do not facilitate a better understanding of the present invention, a discussion of such elements and steps is not provided herein. The disclosure herein is directed to all such variations and modifications to such elements and methods known to those skilled in the art.

Unless defined otherwise, all technical and scientific terms used herein have the same meaning as commonly understood by one of ordinary skill in the art to which this invention belongs. Although any methods and materials similar or equivalent to those described herein can be used in the practice or testing of the present invention, exemplary methods and materials are described.

As used herein, each of the following terms has the meaning associated with it in this section.

The articles “a” and “an” are used herein to refer to one or to more than one (i.e., to at least one) of the grammatical object of the article. By way of example, “an element” means one element or more than one element.

“About” as used herein when referring to a measurable value such as an amount, a temporal duration, and the like, is meant to encompass variations of ±20%, ±10%, ±5%, ±1%, and ±0.1% from the specified value, as such variations are appropriate.

Throughout this disclosure, various aspects of the invention can be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 2.7, 3, 4, 5, 5.3, 6 and any whole and partial increments therebetween. This applies regardless of the breadth of the range.

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), which are incorporated by reference in their entireties. Phosphorescence is described in more detail in U.S. Pat. No. 7,279,704 at cols. 5-6, which are incorporated by reference.

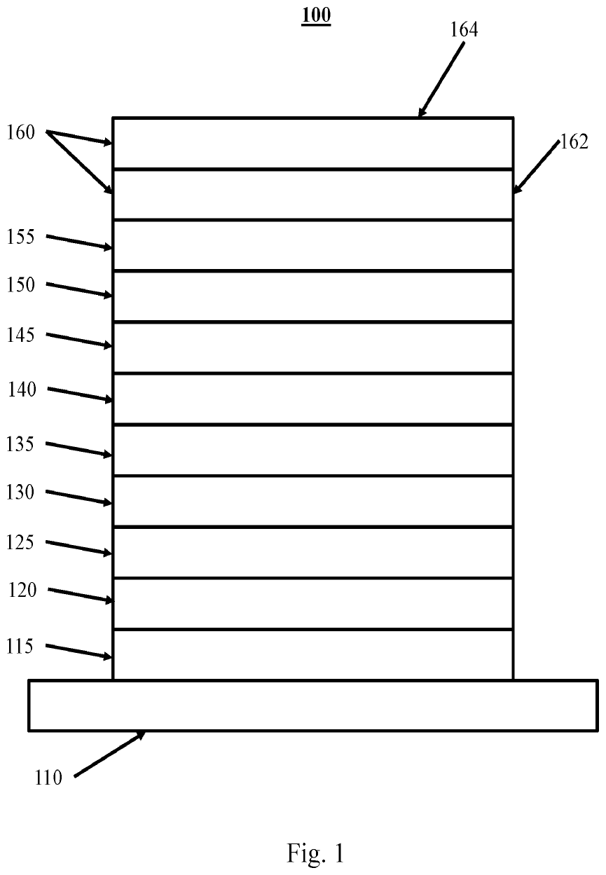

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F₄-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. A description of protective layers may be found in U.S. Patent Application Publication No. 2004/0174116, which is incorporated by reference in its entirety.

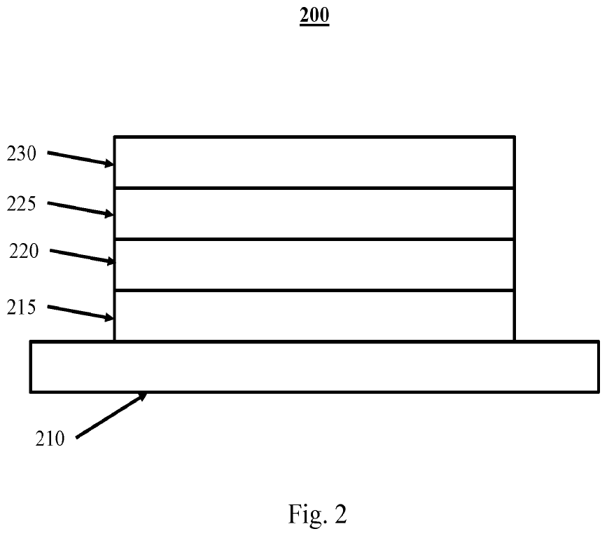

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the disclosure may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve outcoupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

In some embodiments disclosed herein, emissive layers or materials, such as emissive layer 135 and emissive layer 220 shown in FIG. 1 and FIG. 2, respectively, may include quantum dots. The emissive layer may use different emissive display technologies. Such technologies may include inorganic and/or organic devices, such as LEDs, mini LEDs, microLEDs, thin electroluminescent films, organic light emitting devices, and the like. An “emissive layer” or “emissive material” as disclosed herein may include an organic emissive material and/or an emissive material that contains quantum dots or equivalent structures, unless indicated to the contrary explicitly or by context according to the understanding of one of skill in the art. In general, an emissive layer includes emissive material within a host matrix. Such an emissive layer may include only a quantum dot material which converts light emitted by a separate emissive material or other emitter, or it may also include the separate emissive material or other emitter, or it may emit light itself directly from the application of an electric current. Similarly, a color altering layer, color filter, upconversion, or downconversion layer or structure may include a material containing quantum dots, though such layer may not be considered an “emissive layer” as disclosed herein. In general, an “emissive layer” or material is one that emits an initial light based on an injected electrical charge, where the initial light may be altered by another layer such as a color filter or other color altering layer that does not itself emit an initial light within the device, but may re-emit altered light of a different spectra content based upon absorption of the initial light emitted by the emissive layer and downconversion to a lower energy light emission. In some embodiments disclosed herein, the color altering layer, color filter, upconversion, and/or downconversion layer may be disposed outside of an OLED device, such as above or below an electrode of the OLED device.

Unless otherwise specified, any of the layers of the various embodiments may be placed, disposed, or deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processibility than those having symmetric structures, because asymmetric materials may have a lower tendency to recrystallize. Dendrimer substituents may be used to enhance the ability of small molecules to undergo solution processing.

Devices fabricated in accordance with embodiments of the present disclosure may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

According to an embodiment, a consumer electronic device may have an organic light emitting diode (OLED) device including a full-color pixel arrangement that may include a plurality of pixels, with each pixel including a first sub-pixel having a first emissive region configured to emit a first color of light, a second sub-pixel having a second emissive region configured to emit a second color of light, a third sub-pixel having a third emissive region configured to emit a third color of light, and a fourth sub-pixel having the third emissive region and a first color altering layer disposed over at least a portion of the third emissive region. The fourth sub-pixel may be configured to emit a fourth color that is different than the third color. Only one of the first sub-pixel, the second sub-pixel, the third sub-pixel, and the fourth sub-pixel may be configured to emit blue light or red light.

Devices fabricated in accordance with embodiments of the invention can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the invention can be incorporated into a wide variety of consumer products that have one or more of the electronic component modules (or units) incorporated therein. A consumer product comprising an OLED that includes the compound of the present disclosure in the organic layer in the OLED is disclosed. Such consumer products would include any kind of products that include one or more light source(s) and/or one or more of some type of visual displays. Some examples of such consumer products include a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, an automotive display, a video walls comprising multiple displays tiled together, a theater or stadium screen, and a sign. Various control mechanisms may be used to control devices fabricated in accordance with the present invention, including passive matrix and active matrix. Many of the devices are intended for use in a temperature range comfortable to humans, such as 18 C to 30 C, and more preferably at room temperature (20-25 C), but could be used outside this temperature range, for example, from −40 C to 80 C.

Although certain embodiments of the disclosure are discussed in relation to one particular device or type of device (for example OLEDs) it is understood that the disclosed improvements to light outcoupling properties of a substrate may be equally applied to other devices, including but not limited to PLEDs, OPVs, charge-coupled devices (CCDs), photosensors, or the like. More generally, organic devices, such as organic transistors, may employ the materials and structures.

Although exemplary embodiments described herein may be presented as methods for producing particular circuits or devices, for example OLEDs, it is understood that the materials and structures described herein may have applications in devices other than OLEDs. For example, other optoelectronic devices such as organic solar cells and organic photodetectors may employ the materials and structures. More generally, organic devices, such as organic transistors, or other organic electronic circuits or components, may employ the materials and structures.

In some embodiments, the OLED has one or more characteristics selected from the group consisting of being flexible, being rollable, being foldable, being stretchable, and being curved. In some embodiments, the OLED is transparent or semi-transparent. In some embodiments, the OLED further comprises a layer comprising carbon nanotubes.

In some embodiments, the OLED further comprises a layer having a delayed fluorescent emitter. In some embodiments, the OLED comprises a RGB pixel arrangement or white plus color filter pixel arrangement. In some embodiments, the OLED is a mobile device, a hand held device, or a wearable device. In some embodiments, the OLED is a display panel having less than 10 inch diagonal or 50 square inch area. In some embodiments, the OLED is a display panel having at least 10 inch diagonal or 50 square inch area. In some embodiments, the OLED is a lighting panel.

In some embodiments of the emissive region, the emissive region further comprises a host.

In some embodiments, the compound causing light to be generated can be an emissive dopant. In some embodiments, the compound can produce emissions via phosphorescence, fluorescence, thermally activated delayed fluorescence, i.e., TADF (also referred to as E-type delayed fluorescence), triplet-triplet annihilation, or combinations of these processes, including phosphor sensitized fluorescence.

The OLED disclosed herein can be incorporated into one or more of a consumer product, an electronic component module, and a lighting panel. The organic layer can be an emissive layer and the compound can be an emissive dopant in some embodiments, while the compound can be a non-emissive dopant in other embodiments.

The organic layer can also include a host. In some embodiments, two or more hosts are preferred. In some embodiments, the hosts used maybe a) bipolar, b) electron transporting, c) hole transporting or d) wide band gap materials that play little role in charge transport. In some embodiments, the host can include a metal complex. The host can be an inorganic compound.

In some embodiments, at least one of the anode, the cathode, or a new layer disposed over the organic emissive layer functions as an enhancement layer. The enhancement layer comprises a plasmonic material exhibiting surface plasmon resonance that couples to the emitter material and transfers excited state energy from the emitter material to a non-visible mode of surface plasmon polariton. The enhancement layer is provided no more than a threshold distance away from the organic emissive layer, wherein the emitter material has a total non-radiative decay rate constant and a total radiative decay rate constant due to the presence of the enhancement layer and the threshold distance is where the total non-radiative decay rate constant is equal to the total radiative decay rate constant. In some embodiments, the OLED further comprises an outcoupling layer. In some embodiments, the outcoupling layer is disposed over the enhancement layer on the opposite side of the organic emissive layer. In some embodiments, the outcoupling layer is disposed on opposite side of the emissive layer from the enhancement layer but still outcouples energy from the surface plasmon mode of the enhancement layer. The outcoupling layer scatters the energy from the surface plasmon polaritons. In some embodiments this energy is scattered as photons to free space. In other embodiments, the energy is scattered from the surface plasmon mode into other modes of the device such as but not limited to the organic waveguide mode, the substrate mode, or another waveguiding mode. If energy is scattered to the non-free space mode of the OLED other outcoupling schemes could be incorporated to extract that energy to free space. In some embodiments, one or more intervening layer can be disposed between the enhancement layer and the outcoupling layer. The examples for intervening layer(s) can be dielectric materials, including organic, inorganic, perovskites, oxides, and may include stacks and/or mixtures of these materials.

The enhancement layer modifies the effective properties of the medium in which the emitter material resides resulting in any or all of the following: a decreased rate of emission, a modification of emission line-shape, a change in emission intensity with angle, a change in the stability of the emitter material, a change in the efficiency of the OLED, and reduced efficiency roll-off of the OLED device. Placement of the enhancement layer on the cathode side, anode side, or on both sides results in OLED devices which take advantage of any of the above-mentioned effects. In addition to the specific functional layers mentioned herein and illustrated in the various OLED examples shown in the figures, the OLEDs according to the present disclosure may include any of the other functional layers often found in OLEDs.

The enhancement layer can be comprised of plasmonic materials, optically active metamaterials, or hyperbolic metamaterials. As used herein, a plasmonic material is a material in which the real part of the dielectric constant crosses zero in the visible or ultraviolet region of the electromagnetic spectrum. In some embodiments, the plasmonic material includes at least one metal. In such embodiments the metal may include at least one of Ag, Al, Au, Ir, Pt, Ni, Cu, W, Ta, Fe, Cr, Mg, Ga, Rh, Ti, Ru, Pd, In, Bi, Ca alloys or mixtures of these materials, and stacks of these materials. In general, a metamaterial is a medium composed of different materials where the medium as a whole acts differently than the sum of its material parts. In particular, we define optically active metamaterials as materials which have both negative permittivity and negative permeability. Hyperbolic metamaterials, on the other hand, are anisotropic media in which the permittivity or permeability are of different sign for different spatial directions. Optically active metamaterials and hyperbolic metamaterials are strictly distinguished from many other photonic structures such as Distributed Bragg Reflectors (“DBRs”) in that the medium should appear uniform in the direction of propagation on the length scale of the wavelength of light. Using terminology that one skilled in the art can understand: the dielectric constant of the metamaterials in the direction of propagation can be described with the effective medium approximation. Plasmonic materials and metamaterials provide methods for controlling the propagation of light that can enhance OLED performance in a number of ways.

In some embodiments, the enhancement layer is provided as a planar layer. In other embodiments, the enhancement layer has wavelength-sized features that are arranged periodically, quasi-periodically, or randomly, or sub-wavelength-sized features that are arranged periodically, quasi-periodically, or randomly. In some embodiments, the wavelength-sized features and the sub-wavelength-sized features have sharp edges.

In some embodiments, the outcoupling layer has wavelength-sized features that are arranged periodically, quasi-periodically, or randomly, or sub-wavelength-sized features that are arranged periodically, quasi-periodically, or randomly. In some embodiments, the outcoupling layer may be composed of a plurality of nanoparticles and in other embodiments the outcoupling layer is composed of a plurality of nanoparticles disposed over a material. In these embodiments the outcoupling may be tunable by at least one of varying a size of the plurality of nanoparticles, varying a shape of the plurality of nanoparticles, changing a material of the plurality of nanoparticles, adjusting a thickness of the material, changing the refractive index of the material or an additional layer disposed on the plurality of nanoparticles, varying a thickness of the enhancement layer, and/or varying the material of the enhancement layer. The plurality of nanoparticles of the device may be formed from at least one of metal, dielectric material, semiconductor materials, an alloy of metal, a mixture of dielectric materials, a stack or layering of one or more materials, and/or a core of one type of material and that is coated with a shell of a different type of material. In some embodiments, the outcoupling layer is composed of at least metal nanoparticles wherein the metal is selected from the group consisting of Ag, Al, Au, Ir, Pt, Ni, Cu, W, Ta, Fe, Cr, Mg, Ga, Rh, Ti, Ru, Pd, In, Bi, Ca, alloys or mixtures of these materials, and stacks of these materials. The plurality of nanoparticles may have additional layer disposed over them. In some embodiments, the polarization of the emission can be tuned using the outcoupling layer. Varying the dimensionality and periodicity of the outcoupling layer can select a type of polarization that is preferentially outcoupled to air. In some embodiments the outcoupling layer also acts as an electrode of the device.

In embodiments of the disclosed subject matter, a device may include an enhancement layer that is disposed over an emissive area of at least one sub-pixel that is configured to have a Lambertian emission and/or at least one sub-pixel having a microcavity configured for direct emission, as described in detail below. In at least some of such embodiments, the enhancement layer may include a plasmonic structure that is disposed a predetermined threshold distance from the emissive area. The predetermined threshold distance may be a distance at which a total non-radiative decay rate constant is equal to a total radiative decay rate constant. In some of such embodiments, device may include an outcoupling layer is disposed over the enhancement layer on the opposite side of the emissive area.

It is believed that the internal quantum efficiency (IQE) of fluorescent OLEDs can exceed the 25% spin statistics limit through delayed fluorescence. As used herein, there are two types of delayed fluorescence, i.e., P-type delayed fluorescence and E-type delayed fluorescence. P-type delayed fluorescence is generated from triplet-triplet annihilation (TTA).

In some embodiments, a compound in an emissive material and/or layer in an OLED may be used as a phosphorescent sensitizer, where one or multiple layers in the OLED may include an acceptor in the form of one or more fluorescent and/or delayed fluorescence emitters. In some embodiments, the compound can be used as one component of an exciplex to be used as a sensitizer. As a phosphorescent sensitizer, the compound may be capable of energy transfer to the acceptor, and the acceptor may emit the energy or further transfer energy to a final emitter. The acceptor concentrations may range from 0.001% to 100%. The acceptor may be in either the same layer as the phosphorescent sensitizer or in one or more different layers. In some embodiments, the acceptor may be a TADF emitter. In some embodiments, the acceptor may be a fluorescent emitter. In some embodiments, the emission may arise from any or all of the sensitizer, acceptor, and/or final emitter.

On the other hand, E-type delayed fluorescence described above does not rely on the collision of two triplets, but rather on the thermal population between the triplet states and the singlet excited states. Compounds that are capable of generating E-type delayed fluorescence are required to have very small singlet-triplet gaps. Thermal energy can activate the transition from the triplet state back to the singlet state. This type of delayed fluorescence is also known as thermally activated delayed fluorescence (TADF). A distinctive feature of TADF is that the delayed component increases as temperature rises due to the increased thermal energy. If the reverse intersystem crossing rate is fast enough to minimize the non-radiative decay from the triplet state, the fraction of back populated singlet excited states can potentially reach 75%. The total singlet fraction can be 100%, far exceeding the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (AES-T). Organic, non-metal containing, donor-acceptor luminescent materials may be able to achieve this. The emission in these materials is often characterized as a donor-acceptor charge-transfer (CT) type emission. The spatial separation of the HOMO and LUMO in these donor-acceptor type compounds often results in small AES-T. These states may involve CT states. Often, donor-acceptor luminescent materials are constructed by connecting an electron donor moiety such as amino- or carbazole-derivatives and an electron acceptor moiety such as N-containing six-membered aromatic ring.

Additionally, in some embodiments, an emissive region may have one or more emissive layer. In an embodiment, the number of layers in each emissive region of each device may be the same. In alternative embodiment, the number of layers in each emissive region of each device may be different. In yet another alternative embodiment, the number of layers in some emissive regions of each device may be the same and some emissive regions of each device may be different. In some embodiments, an emissive layer of the one or more emissive layers of any emissive region may comprise a phosphorescent material, a fluorescent material or any combination thereof. In some embodiments, the emissive regions in the device may comprise a sensitizer and an acceptor with various sensitizing device characteristics disclosed in this application.

Disclosed herein is a device that uses the near-field of surface plasmons to transfer energy from electrically-formed excitons to chromophores. More particularly, some embodiments of the disclosed device use electrodes to inject electrons and holes, which form excitons. These excitons couple to surface plasmon polariton modes in a planar silver film. These plasmons excite molecules on the opposite side of the silver film.

The disclosed device could be used for driving photochemical reactions, or for biosensing applications, for blue OLEDs based off of triplet fusion upconversion. For the blue OLED, the device would operate by having an upconversion film as the device's acceptor layer, which would potentially be much more stable than a conventional OLED blue emissive layer which features destructive triplet-charge annihilation. This would potentially be useful for the display industry, since stable blue OLEDs are still an outstanding research challenge.

An important aspect of the disclosed device is its use of near-field energy transfer, as opposed to typical far-field excitation. For solution-phase applications, organic chromophores are typically excited with far-field light sources such as lamps and lasers. This requires that a photon emitted by the light source is appropriately ‘guided’ to the chromophore without parasitic absorption, reflection, or scattering. In addition, far-field photons from an excitation source can convolute signals emitted from a sample. Near-field energy transfer to chromophores can have several advantages over far-field transfer. For example, a near-field is ‘invisible’ in the absence of an absorptive medium, and thus cannot convolute signals emitted from a sample. In addition, the non-traveling virtual photons that mediate energy transfer do not require ‘guidance’ as do far field photons, because the near-field energy transfer process relies on an acceptor being located within the near-field. The local field enhancement from the SPPs may also be used in some embodiments for triplet fusion upconversion, which often requires large fields to be enabled, which is an important feature of the disclosed device.

For solution phase applications, the disclosed device can be delaminated and dissolved when submerged in the solution. This shortcoming could potentially be overcome by appropriate thin film encapsulation and designing materials to survive upon submersion in organic solvents.

For upconversion OLED applications, the disclosed device has an upper bound of 50% internal quantum efficiency, since two electrically pumped excitons are required to form one blue emitter. While this may not be overcome, a 50% internal quantum efficiency may be more than enough to create an industrially viable product.

For blue OLEDs, the disclosed device could easily be integrated into existing top-emitting OLED structures that have been commercialized for displays. The potential stability enhancement from this design could allow for better displays.

The disclosed device could also potentially be used in a photochemical flow reactor with microscopic dimensions. This could allow for larger surface areas of light emission, and thus allow for a more power efficient design.

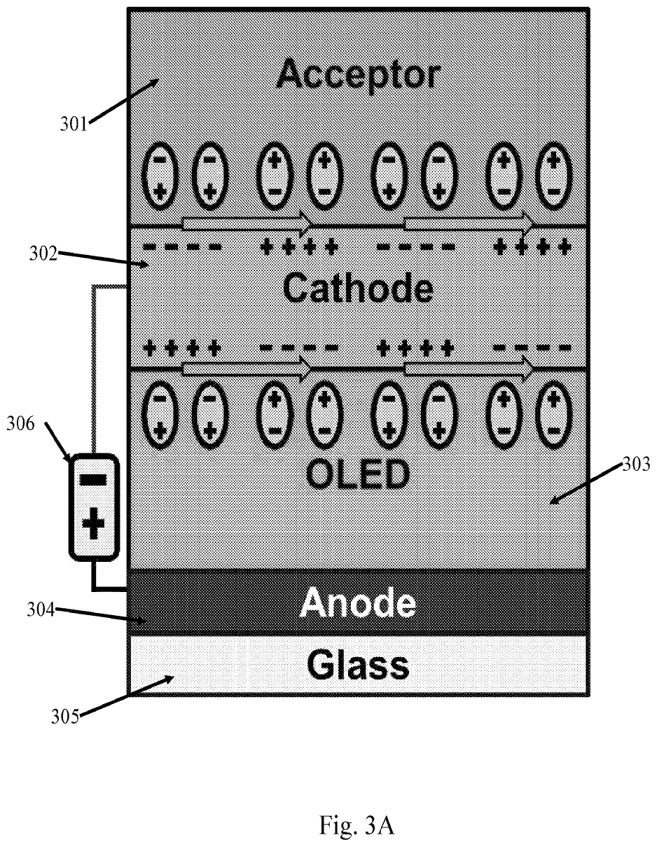

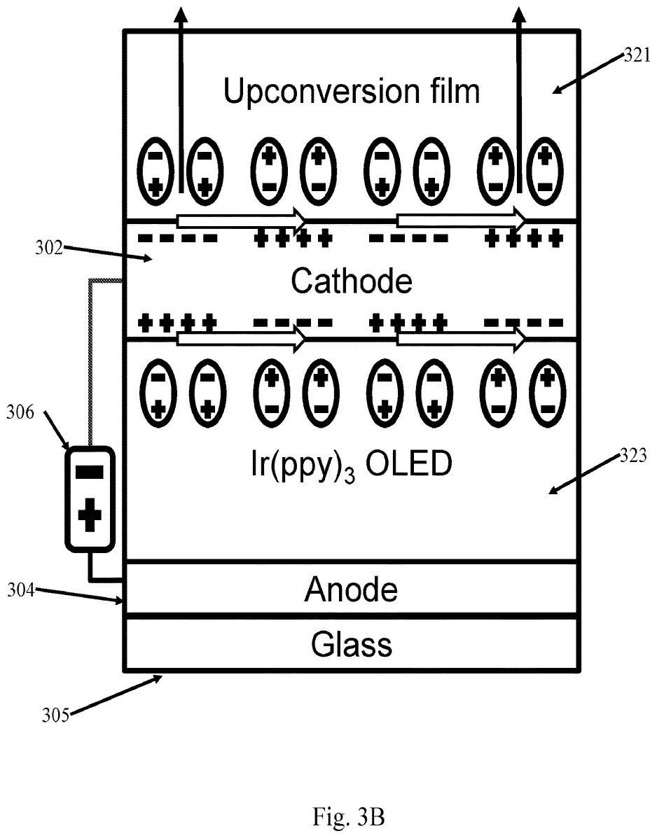

In some embodiments disclosed herein, an organic optoelectronic diode that achieves near-field energy transfer to molecules in solution via SPPs is shown. An exemplary schematic for a plasmon mediated energy transfer (PMET) diode is shown in FIG. 3A. In contrast to a common transparent-substrate-emitting OLED that seeks to minimize coupling of emissive dipoles to SPP modes (P. A. Hobson, et al., IEEE j. Sel. Topics in Quantum Elect., 2002), or scatters the non-emissive SPP modes into visible far-field photons (P. A. Hobson, et al., Adv. Mater., 2002; M. A. Fusella, et al., Nature, 2020), the disclosed PMET diode of FIG. 3A seeks to maximize SPP coupling to excite acceptor molecules on top of the cathode 302. The PMET diode adopts the basic structure of an OLED, with the OLED 303 shown in detail in FIG. 3C. As shown in FIG. 3C, the OLED 303 includes a phosphor-doped emissive layer (EML) 314 sandwiched by an electron injection layer 312, a hole injection layer 316, and electron (313) and hole (315) transport layers (ETI/HTL). Electrons and holes are injected from the cathode 302 and anode 304, respectively, to form donor excitons in the EML 314. The silver cathode 302 sustains traveling SPPs generated by donor excitons, and the evanescent near-field of these SPPs excites external acceptor molecules in the acceptor layer 301 above the cathode 302. In some embodiments, a device as disclosed herein may comprise a thin-film, high refractive index (n) dielectric layer 311 above the cathode increases outcoupling to the acceptors. In some embodiments, the dielectric layer 311 may comprise Tellurium Dioxide. In some embodiments, the dielectric layer 311 may comprise Zinc Sulfide, Silicon Nitride, or any other suitable material. The dielectric layer 311 may have a thickness of between 5 nm and 50 nm, or between 10 nm and 40 nm, or between 10 nm and 30 nm, or between 15 nm and 25 nm, or between 18 nm and 23 nm, or about 21 nm. The dielectric layer 311 may have a refractive index of at least 1.3, at least 1.4, at least 1.5, at least 1.6, at least 1.7, at least 1.8, at least 1.9, at least 2, at least 2.1, at least 2.2, at least 2.3, at least 2.4, at least 2.5, or any suitable refractive index. The disclosed PMET diode demonstrates excitation of solution-phase acceptors.

With reference to FIG. 3B, an additional variant of the disclosed device is shown. The variant device comprises an Ir(ppy)₃ green emitting OLED 323 in a similar device structure to the device of FIG. 3A. The device of FIG. 3B comprises an upconversion film 321 positioned above the cathode 302. The surface plasmons excite sensitizer molecules in the upconversion film, which drives the upconversion process and emits blue light. In some embodiments, the upconversion film 321 may comprise a sensitizer comprising platinum octaethylporphyrin (PtOEP) (40 vol. %) mixed with 1,1′-(2,5-Dimethyl-1,4-phenylene)dipyrene (DMPPP) (60 vol. %) at an approximate thickness of 5 nm-15 nm, or 5 nm-12 nm, or 5 nm-10 nm, or about 8 nm. In some embodiments, the upconversion film 321 may further comprise an annihilator material, for example a layer of neat 2-methyl-9,10-bis(naphthalen-2-yl)anthracene (MADN) at approximately 40-120 nm, or 60-100 nm, or 70-90 nm, or about 80 nm. In some embodiments, a mixture of 4,4′-Bis[4-(diphenylamino)styryl]biphenyl (BDAVBi) (1-3 vol. %) in MADN may be used as an annihilator layer, where MADN annihilates triplets and BDAVBi serves as a high photoluminescence quantum yield sink. In other embodiments, 9,10-diphenylanthracene (DPA) may be used as an annihilator, and separately or in combination, Palladium Octaethylporphyrin (PdOEP) may be used as a sensitizer.

Although the device of FIG. 3B shows a green emitting OLED 323, it is understood that in other embodiments, the main emissive layer could be any emissive layer, including but not limited to a red emissive layer, a yellow emissive layer, an orange emissive layer, a blue emissive layer, a violet emissive layer, a near-IR emissive layer, a far-IR emissive layer, or any other suitable emissive layer.

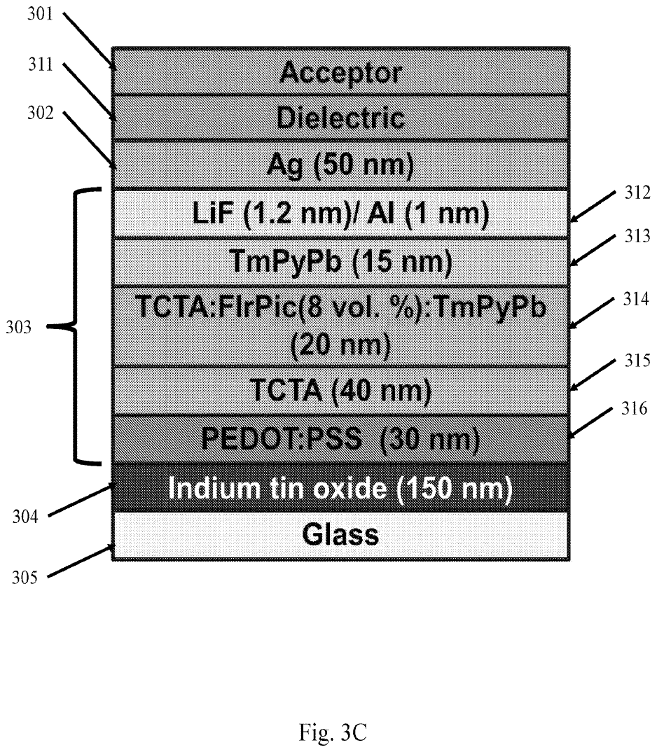

As disclosed herein, upconversion is a nonlinear optical process, characterized by a threshold intensity Iₜₕ that marks the transition between nonlinear and linear regime. Some embodiments of the device disclosed in FIG. 3B are configured to concentrate electric fields within the upconversion layer by virtue of the surface plasmons, and as a result the Iₜₕ of the disclosed device is lower than an upconverting device that uses conventional far-field excitation. FIG. 4A and FIG. 4B show exemplary diagrams of the disclosed device (FIG. 4A) and a conventional far-field device 4B. The disclosed device in FIG. 4A has the OLED 323 positioned opposite the cathode from the sensitizer layer 402 and annihilator layer 401, whereas a conventional device may comprise a remote light source, for example a laser 404 shining through a substrate 403 and then through the sensitizer layer 402 and annihilator layer 401.

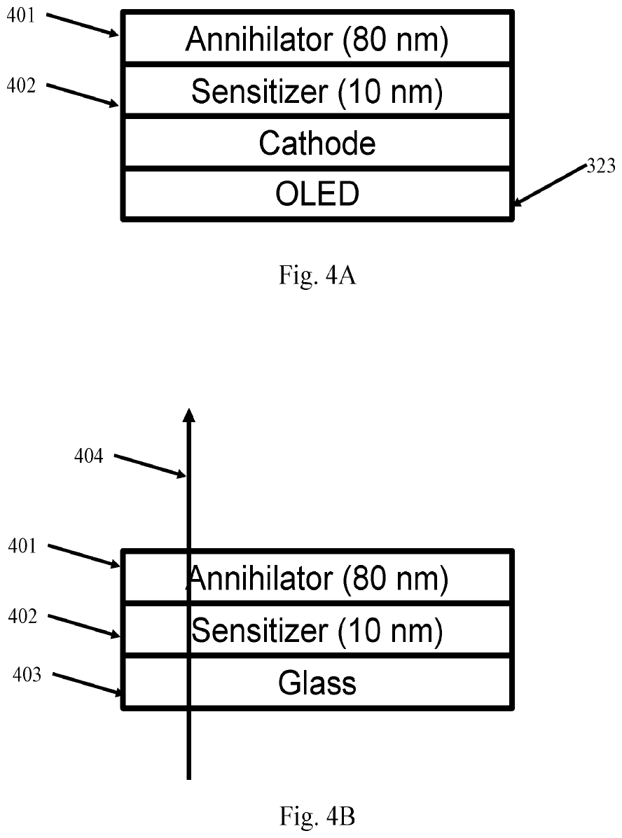

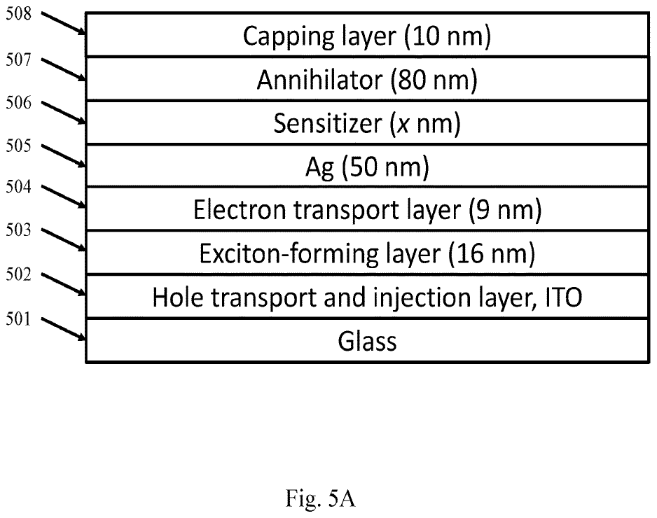

Two device structures of the disclosed architecture of FIG. 3B are shown in FIG. 5A and FIG. 5B. The device of FIG. 5A includes a substrate 501 which may be a transparent substrate, for example glass. A hole transport and injection layer 502, which may comprise Indium Tin Oxide (ITO) is positioned over substrate 501. In some embodiments, hole transport and injection layer 502 may comprise an anode. In some embodiments, the hole transport and injection layer 502 may comprise, from bottom to top, ITO (150 nm), PEDOT:PSS (30 nm), TAPC (20 nm), and TCTA (10 nm). The device of FIG. 5A further comprises an exciton forming layer 503, which may comprise TCTA:Ir(ppy)₃:TpPyPb, an electron transport layer 504 which may comprise TpPyPb, a second electrode, for example a silver cathode 505, a sensitizer layer 506 which may comprise PtOEP (40 vol. %):DMPPP (60 vol. %), an annihilator layer 507 which may comprise MADN, and a capping/encapsulation layer 508 which may comprise 1,3-Bis(N-carbazolyl)benzene (mCP).

The device of FIG. 5B comprises a substrate 511 which may be a transparent substrate, for example glass. A hole transport and injection layer 512, which may comprise Indium Tin Oxide (ITO) is positioned over substrate 511. In some embodiments, an electrode, for example an anode, may be positioned between substrate 511 and hole transport and injection layer 512. The device of FIG. 5B further comprises an exciton forming layer 513, an electron transport layer 514, a second electrode, for example a silver cathode 515, a sensitizer layer 516, an annihilator layer 517, and a second sensitizer layer 518. In some embodiments, a device of FIG. 5B may also comprise a capping/encapsulation layer positioned over the sensitizer layer 518. The materials used in FIG. 5A may also be used in the corresponding layers of the device structure of FIG. 5B.

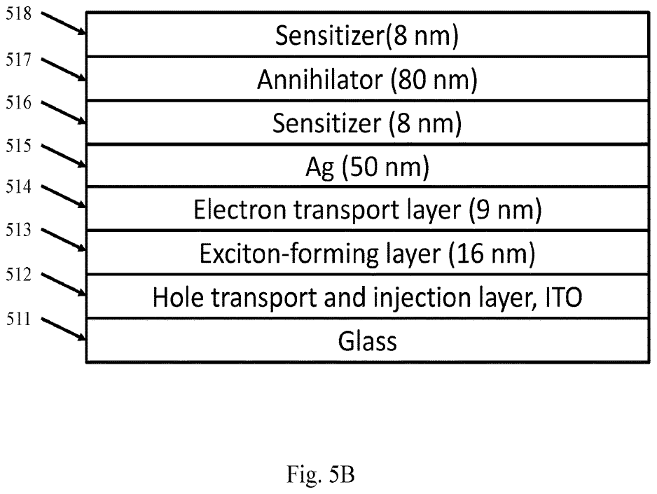

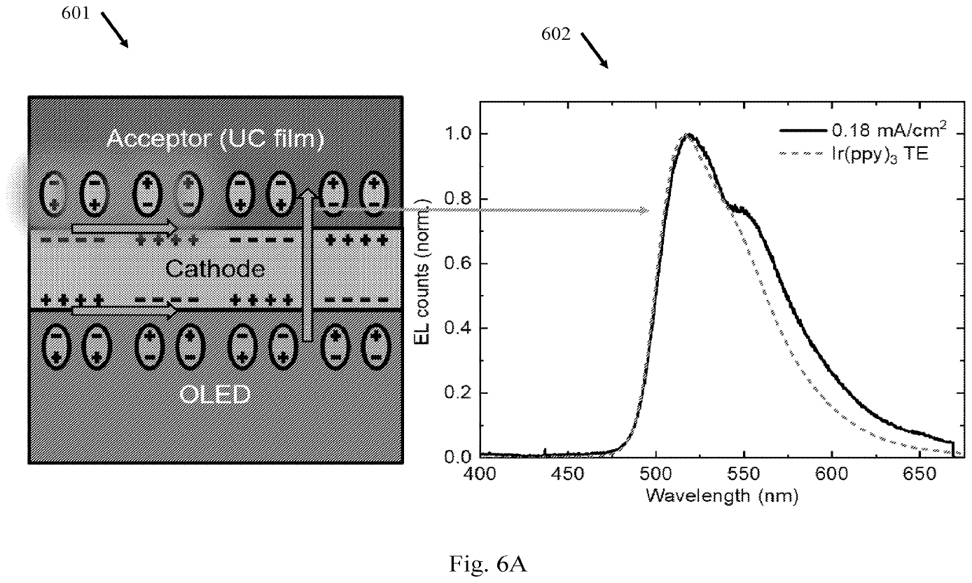

With reference to FIG. 6A, the graph 602 and, and the 612 in FIG. 6B, are proof that the blue emission seen from the device is a result of upconversion. The green emission seen (shown in the EL spectra on the right) from the top of the device is a result of direct Ir(ppy)₃ emission from the OLED through the silver cathode, at a current density of 0.18 mA/cm². At this low current density, no blue emission is seen, only the green Ir(ppy)₃ emission.

By contrast, in FIG. 6B, an EL spectrum graph 612 is shown at a higher current density of 1200 mA/cm². In addition to the main green emissive peak 615, at a higher current density, a second blue emissive peak 614 emerges, driven by upconversion 616 in the upconversion film. As recited above, upconversion only takes place at higher pump intensities, and so the fact that blue emission is only seen at higher current means that the blue emission is the result of upconversion.

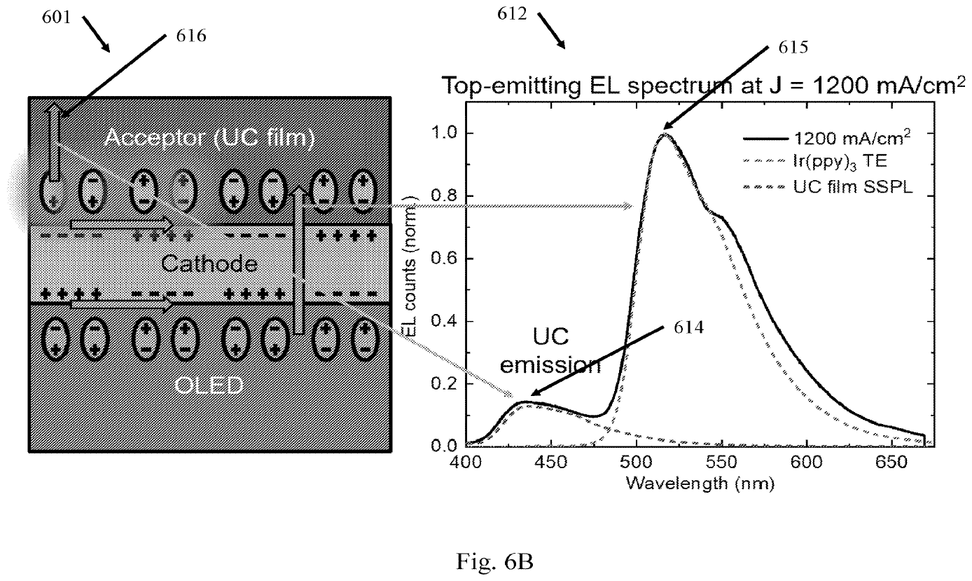

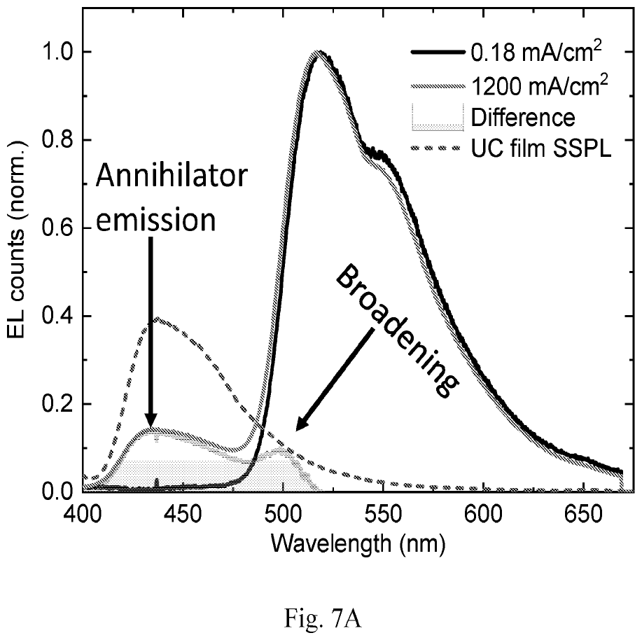

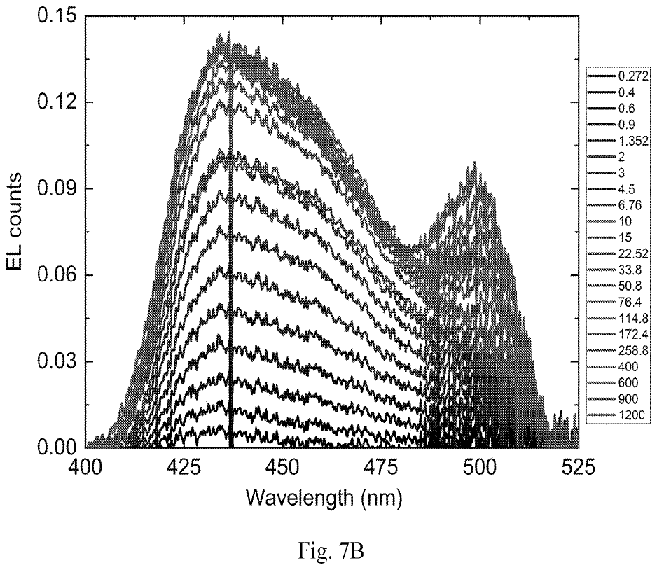

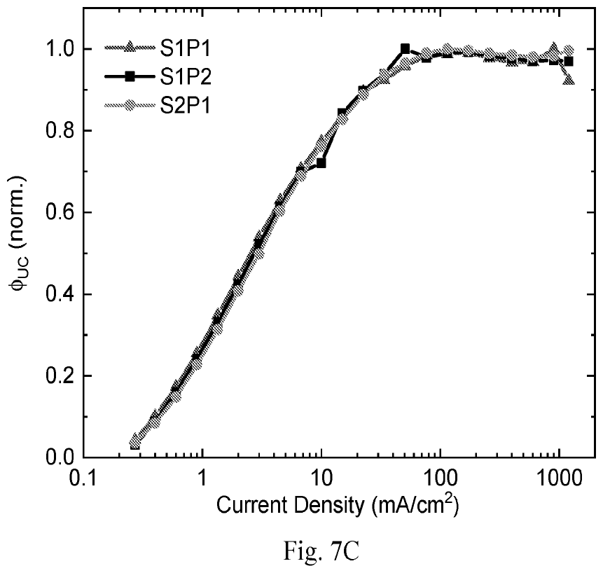

FIG. 7A and FIG. 7B shows how the amount of emission from the device that results from upconversion is derived compared to the total, which also includes the green Ir(ppy)₃ direct emission. At each current density measured, the spectrum at each current density was subtracted from the spectrum at the lowest current density measurable. The result of that is shown in FIG. 7B. The current densities measured and presented in FIG. 7B are, in mA/cm²: 0.272, 0.4, 0.6,0.9, 1.352, 2, 3, 4.5, 6.76, 10, 15, 22.52, 33.8, 50.8, 76.4, 114.8, 172.4, 258.8, 400, 600, 900, 1200.

With reference to the device 601, shown in FIG. 6A and FIG. 6B, the relative upconversion efficiency may be calculated as follows. First, the brightness of direct emission from the OLED I_{dir} is:

$${I}_{dir} = J \times IQE ( J ) \times {η}_{out , dir} \qquad Equation 1$$

where J is the current, IQE(J) is the internal quantum efficiency, and η_{out,dir} is the outcoupling efficiency of the device, i.e. the fraction of photons generated that become a directly emitted photon contributing to I_{dir}.

The brightness of the upconversion emission, meanwhile, is given by:

$${I}_{UC} = J \times IQE ( J ) \times {ϕ}_{UC} ( J ) \times {ϕ}_{PMET}^{*} \times {η}_{out , UC} \qquad Equation 2$$

where I_{UC} is the brightness of upconverted emission from the device, J is the current IQE (J) is the internal quantum efficiency, φ_{UC}(J) is the quantum efficiency of the upconversion film, φ_{PMET} is the ratio of sensitizer molecules excited to the number of excitons generated in the OLED emissive layer, η_{out,UC} is the optical outcoupling efficiency of upconverted photons. And so therefore

$${ϕ}_{UC} ( J ) ∝ \frac{{I}_{uc}}{{I}_{dir}} \qquad Equation 3$$

where Φ_{UC}(J) is the quantum efficiency of the upconversion film, I_{UC} is the brightness of upconverted emission from the device, and I_{dir} is the brightness of direct emission from the device.

Equation three results from placing the right hand side of Equation 2 above the right hand side of Equation 1, showing that all terms cancel (J, IQE(J)) except ones that are constant in current density, (φ_{PMET}, κ_{out,UC}, η_{out,dir}) and rearranging. Thus, the relative (but not absolute) value of Φ_{UC}(J) can be determined by measuring the ratio between I_{UC} and I_{dir}, which is proportional to Φ_{UC}(J).

The graph of FIG. 7C represents relative upconversion efficiency, and is calculated by normalizing the curves in the graph of FIG. 7B to the same value and then integrating the graph within the range of 425 to 450 nm. This value is proportional to the upconversion efficiency, and so the graph of FIG. 7C shows the normalized upconversion efficiency plotted versus current density on the x-axis.

In order to determine the Iₜₕ of the disclosed device, the power incident upon the acceptor layer is calculated, and the following equation is used, where Equation 4 simplifies to Equation 5. Iₜₕ is the power threshold for upconversion, defined as the power at which the upconversion efficiency reaches 50% of its maximum value.

$${P}_{acc} = \frac{electrons}{second} \times \frac{energy}{photon} \times \frac{emitted photons}{electron} \qquad Equation 4$$

$$= \frac{J}{q} \times \frac{h c}{λ} \times IQE \qquad Equation 5$$

The IQE was assumed to be 100%. If this assumption was wrong, performance was underestimated because it would predict a larger power than the reality, leading to an overestimate of Iₜₕ which is desired to be as low as possible. In Equation 4, λ was set to 513 nm because it is the peak of Ir(ppy)₃ emission.

The graph of FIG. 7D shows an example of a decrease in threshold in a plasmon device (shown in FIG. 4A) versus optical pumping (device shown in FIG. 4B). The devices used in the measurements shown in FIG. 7D corresponded to the devices of FIG. 4A and FIG. 4B but additionally included a 10 nm capping layer of mCP. Using the two disclosed device structures, the normalized upconversion efficiency is plotted versus power density (power density for the device shown in FIG. 4A calculated from Equation 5) for optical and plasmon OLED excitation, showing a large decrease in the upconversion threshold using the disclosed device.

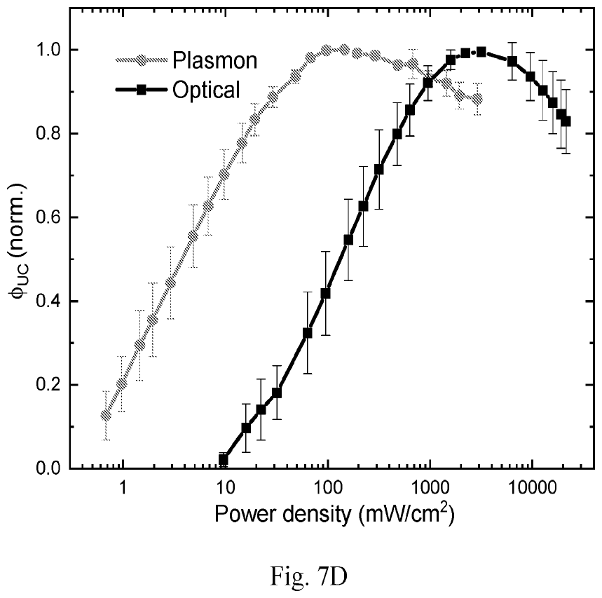

With reference to FIG. 8, an exemplary white OLED is shown. The device in FIG. 8 comprises a glass substrate 801 and a first electrode 802, which in some embodiments may be a transparent electrode, for example a transparent anode comprising ITO. Charge injection/transport layers 803 and 804 may for example be hole transport/injection layers or electron blocking layers. The device of FIG. 8 further comprises a red emissive layer 805 to add to the green emissive layer 806, in order to better produce white light from the device. Further charge transport/injection layers 807 and 808 may be positioned over the emissive layer, and layer 808 may in some embodiments comprise a second electrode, for example a cathode. The upconversion layers 809 and 810 are configured for blue emission from the SPP mode of the green emitter. In some embodiments, the device of FIG. 8 may further comprise a capping layer, for example a 10 nm mCP capping layer. All layer thicknesses in the device of FIG. 8 are provided, but the red emissive layer 805 was evaluated at thicknesses of 0.25, 0.5, 1, or 2 nm. In some embodiments, a thin or ultrathin red layer may be used in order to prevent the red emission from becoming too large of a component of the total emitted light.

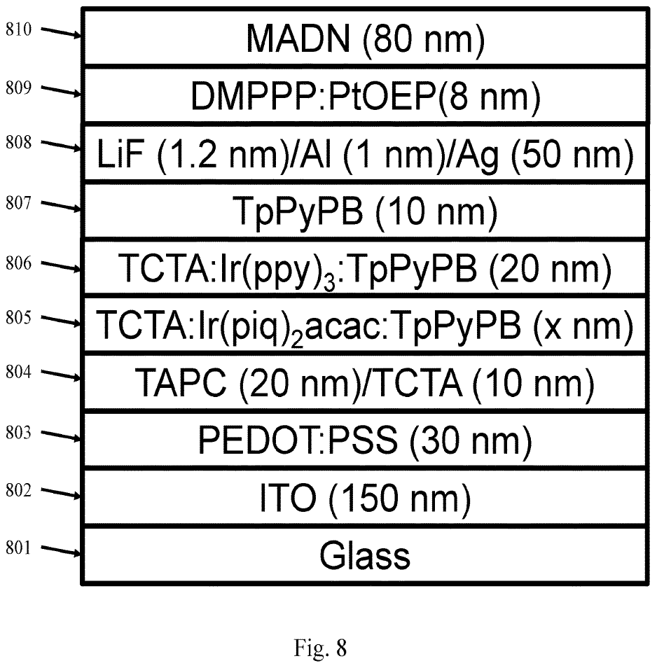

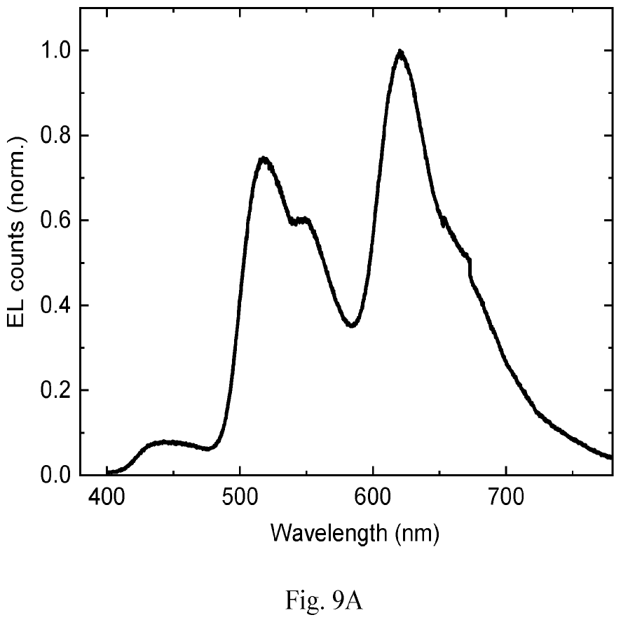

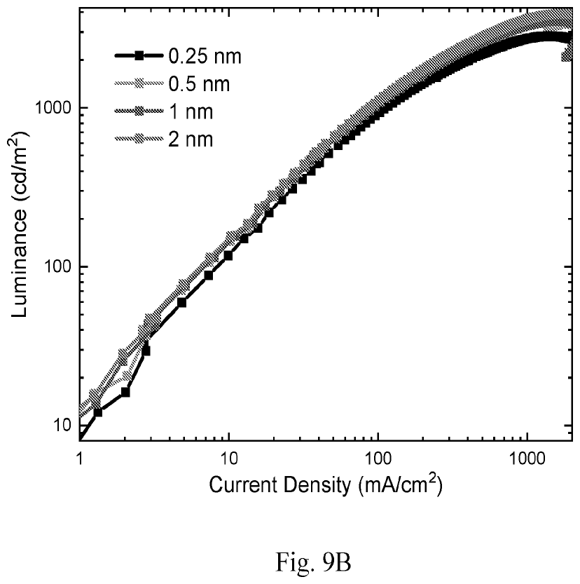

A graph of normalized emission for the device is shown in FIG. 9A. The values were calculated and then re-calculated after setting the spectrum to 0 below 480 nm in order to determine how much the upconverted emission improves metrics. The graph of FIG. 9A shows the spectrum from the white OLED at 102.4 mA/cm². The second row of Table 1 shows what these metrics would be without any blue emission.

TABLE 1

| Sample | CIE (x, y) | CRI | CCT |
|---|---|---|---|
| 1 nm EML at 1000 cd/m² | (0.447, 0.470) | 82.5 | 3300 |
| “ “ with = 0 for <480 nm | (0.465, 0.500) | 65.0 | 3200 |

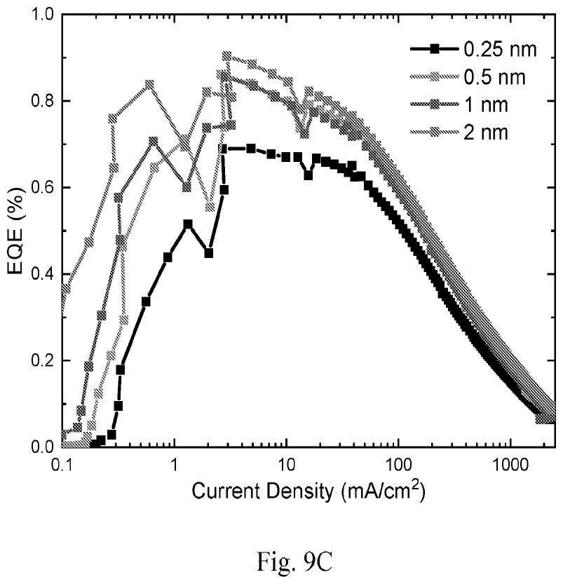

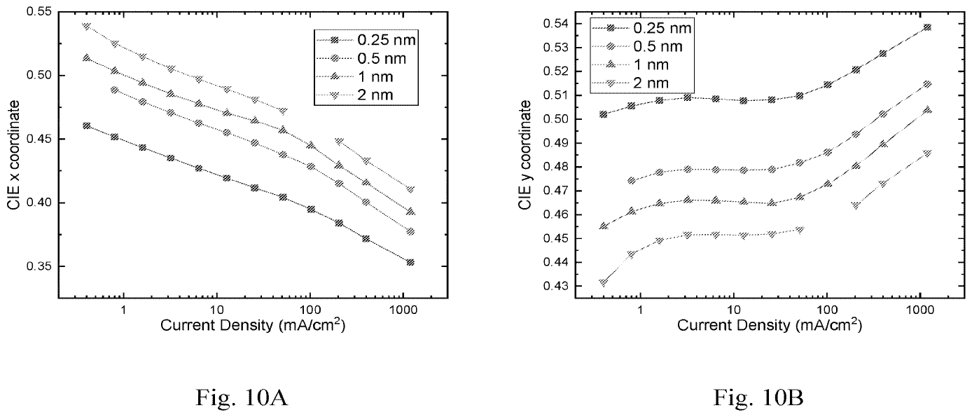

FIG. 9B shows luminance metrics of the white OLED of FIG. 8 at different thicknesses of the red emissive layer 805, and FIG. 9C shows a graph of EQE of the white OLED of FIG. 8. FIG. 10A, FIG. 10B, FIG. 10C, and FIG. 10D show graphs of further OLED metrics (CIE coordinates, CCT, and CRT, respectively) across different current densities and for different red EML thicknesses. In one embodiment, with a red EML thickness of 1 nm and at a luminance of 1000 cm/m², the device had CIE coordinates of (0.447,0.470) with a CRI of 82.5 and a CCT of 3300.

Combination with Other Materials

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

Various materials may be used for the various emissive and non-emissive layers and arrangements disclosed herein. Examples of suitable materials are disclosed in U.S. Patent Application Publication No. 2017/0229663, which is incorporated by reference in its entirety.

### Conductivity Dopants

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer.

### HIL/HTL

A hole injecting/transporting material to be used in the present disclosure is not particularly limited, and any compound may be used as long as the compound is typically used as a hole injecting/transporting material.

### EBL

An electron blocking layer (EBL) may be used to reduce the number of electrons and/or excitons that leave the emissive layer. The presence of such a blocking layer in a device may result in substantially higher efficiencies, and or longer lifetime, as compared to a similar device lacking a blocking layer. Also, a blocking layer may be used to confine emission to a desired region of an OLED. In some embodiments, the EBL material has a higher LUMO (closer to the vacuum level) and/or higher triplet energy than the emitter closest to the EBL interface. In some embodiments, the EBL material has a higher LUMO (closer to the vacuum level) and or higher triplet energy than one or more of the hosts closest to the EBL interface. In one aspect, the compound used in EBL contains the same molecule or the same functional groups used as one of the hosts described below.

### Host

The light emitting layer of the organic EL device of the present disclosure preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. Any host material may be used with any dopant so long as the triplet criteria is satisfied.

### HBL

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further from the vacuum level) and or higher triplet energy than the emitter closest to the HBL interface. In some embodiments, the HBL material has a lower HOMO (further from the vacuum level) and or higher triplet energy than one or more of the hosts closest to the HBL interface.

### ETL

An electron transport layer (ETL) may include a material capable of transporting electrons. The electron transport layer may be intrinsic (undoped), or doped. Doping may be used to enhance conductivity. Examples of the ETL material are not particularly limited, and any metal complexes or organic compounds may be used as long as they are typically used to transport electrons.

### Charge Generation Layer (CGL)

In tandem or stacked OLEDs, the CGL plays an essential role in the performance, which is composed of an n-doped layer and a p-doped layer for injection of electrons and holes, respectively. Electrons and holes are supplied from the CGL and electrodes. The consumed electrons and holes in the CGL are refilled by the electrons and holes injected from the cathode and anode, respectively; then, the bipolar currents reach a steady state gradually. Typical CGL materials include n and p conductivity dopants used in the transport layers.

As previously disclosed, OLEDs and other similar devices may be fabricated using a variety of techniques and devices. For example, in OVJP and similar techniques, one or more jets of material is directed at a substrate to form the various layers of the OLED.

### Experimental Examples

The invention is further described in detail by reference to the following experimental examples. These examples are provided for purposes of illustration only, and are not intended to be limiting unless otherwise specified. Thus, the invention should in no way be construed as being limited to the following examples, but rather, should be construed to encompass any and all variations which become evident as a result of the teaching provided herein.

Without further description, it is believed that one of ordinary skill in the art can, using the preceding description and the following illustrative examples, make and utilize the system and method of the present invention. The following working examples therefore, specifically point out the exemplary embodiments of the present invention, and are not to be construed as limiting in any way the remainder of the disclosure.

### Device Fabrication

Glass substrates with pre-patterned ITO with a sheet resistance of 15 Ω/sq were sonicated in soapy deionized water, deionized water, acetone, and isopropanol heated to 40° C. for 15 min each, followed by an O₂ plasma treatment for 10 min. PEDOT:PSS was subsequently spun-cast on the ITO substrates at 4000 rpm with 4000 rpm/s acceleration and annealed in air at 140° C. for 10 min. The samples were then brought into a vacuum thermal evaporation (VTE) chamber, having a base pressure ~2×10⁻⁶ Torr for thermal evaporation of 4,4′,4″-tris(carbazole-9-yl)triphenylamine (TCTA) (40 nm, deposition rate 1 Å/s), TCTA (0.5 Å/s): (FIrPic) (8 vol. %, 0.12 Å/s): TmPyPb (1 Å/s) (20 nm total), TmPyPb (15 nm, 1 Å/s), LiF (1.2 nm, 0.04 Å/s), Al (1 nm, 0.5 Å/s), and Ag (50 nm, 1 Å/s). For solution-phase acceptor experiments, the substrates were then placed into a thermal atomic layer deposition system with a chuck temperature of 80° C. to deposit Al₂O₃. Trimethylaluminum and water were alternatingly pulsed for 75 cycles, corresponding to an approximate Al₂O₃ thickness of 6 nm. The samples were then brought back into the VTE chamber to deposit 21 nm of TeO₂. For solid-state acceptor experiments, Alq₃ (10 nm, 1 Å/s), LiF (45 nm total, 0.2-1 Å/s), and DCM (20 vol. %, 0.2 Å/s): Alq₃ (1 Å/s) (65 nm total) were then evaporated for target devices, or Alq₃ (65 nm, 1-2 Å/s) for control devices.

### Optoelectronic Measurements:

Saturated solutions of DCM (13 mM) and TMB (0-24 mM) were prepared in an N₂ glovebox using anhydrous MeCN. Approximately 100 μL of solution was placed onto the top of each device and sealed using a Gene Frame and 150 μM-thick coverglass to prevent evaporation. The TE-EQE and current-voltage characteristics were measured using a customized setup consisting of a sourcemeter and a calibrated Si photodiode positioned perpendicular to the device, measured with a picoammeter. Steady-state EL spectra were collected using a spectrometer coupled with a CCD camera. Transient photoluminescence decay curves were recorded using a photoluminescence spectrometer with 375 nm excitation. Absorption spectra were recorded using a UV-vis-NIR spectrometer. Photoexcited Stern-Volmer measurements were conducted using a 450 nm laser diode excitation source and 1 cm path length quartz cuvettes. Device layer thicknesses were calibrated using variable angle spectroscopic ellipsometry (VASE) of thin films on silicon.

### Results

To study the working mechanisms of the PMET diode, both in-coupling of donor excitons to SPP modes and outcoupling of SPP modes to acceptors were measured. To study in-coupling, performed time-resolved photoluminescence (TRPL) measurements were performed on the PMET diode while sweeping the distance between the EML donor excitons and the cathode by changing the thickness of the 1,3,5-tri(m-pyridin-3-ylphenyl)benzene (TmPyPb) ETL. FIG. 3C shows the device stack for the PMET diode used in the present experiment, which was based on the OLED reported by Chen et al. (Y. Chen, et al., Appl. Phys. Lett., 2012) with alterations made to improve outcoupling informed by the optical simulation model from Celebi et al. (K. Celebi, et al., Optics Express, 2007). Specifically, the The ETL thickness was decreased from 30 nm to 15 nm to increase the surface plasmon coupling, the MoO₃ hole injection layer was replaced with PEDOT:PSS to improve device wetting and survivability in solvent, the cathode was changed from aluminum to silver to allow for longer propagation length SPPs, and a 21 nm TeO₂ dielectric layer was deposited on top of the cathode to improve SPP outcoupling.

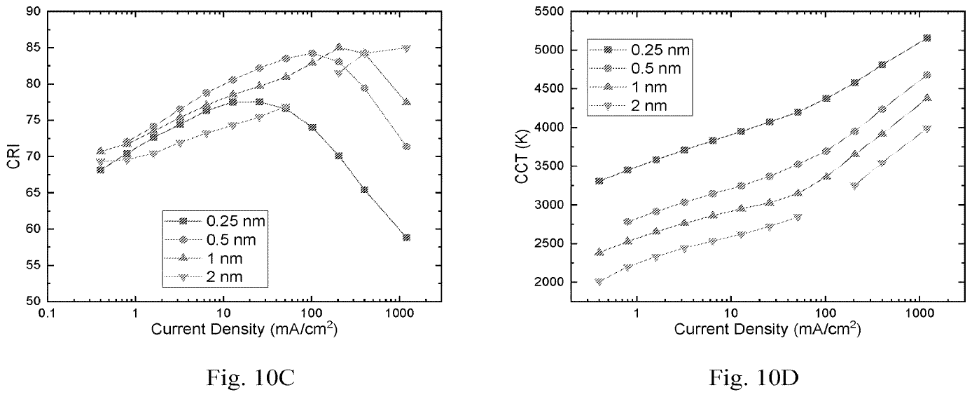

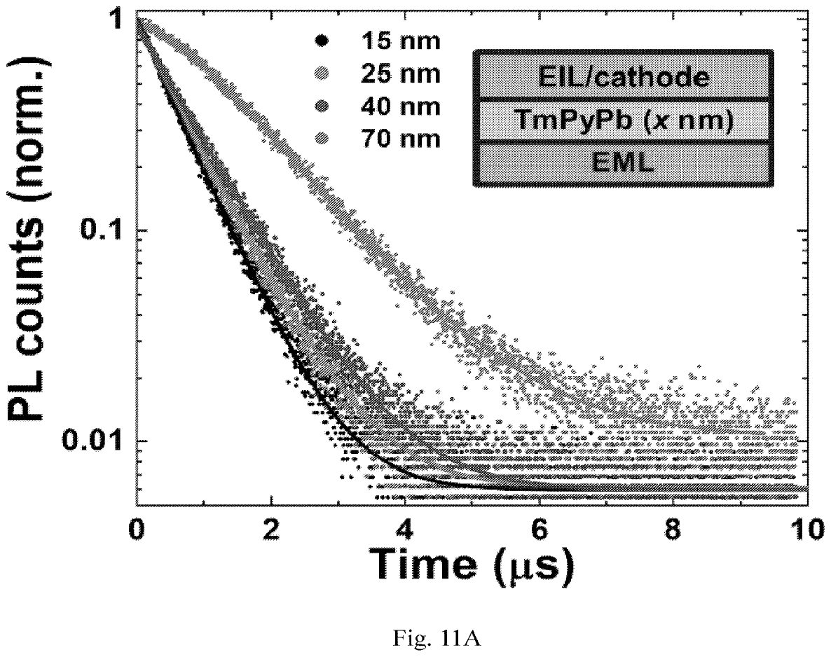

The donor molecule used in the disclosed structure was the common sky-blue OLED phosphor bis[2-(4,6-difluorophenylpyridinato-C²,N](picolinato)iridium(II) (FIrPic). FIG. 11A shows that the photoluminescence (PL) lifetime of the donor monotonically decreases from 1.17 to 0.60 μs as the ETL thickness is reduced from 70 nm to 15 nm. The decrease of PL lifetime is attributed to Purcell enhancement from increased SPP in-coupling. (W. L. Barnes, J. Modern Optics, 1998) This result helps to inform device design to optimize the tradeoff between optoelectronic performance of the OLED structure and optical coupling to acceptors.

With reference to FIG. 11A and FIG. 11B, FIG. 11A shows a graph of TRPL decay curves for the structure shown in the inset. As the ETL thickness increases from 15 to 70 nm, the PL lifetime increases monotonically (0.60, 0.70, 0.78, 1.17 μs) attributed to a lessening of the plasmonic Purcell enhancement. FIG. 11B is a graph of TE-EQE measurements of the PMET diode with a solid-state acceptor separated from the cathode by various thickness of a LiF spacer. As the thickness of the spacer increases from 2.5 to 45 nm, the TE-EQE drops, suggesting that emission originates from a near-field energy transfer process.

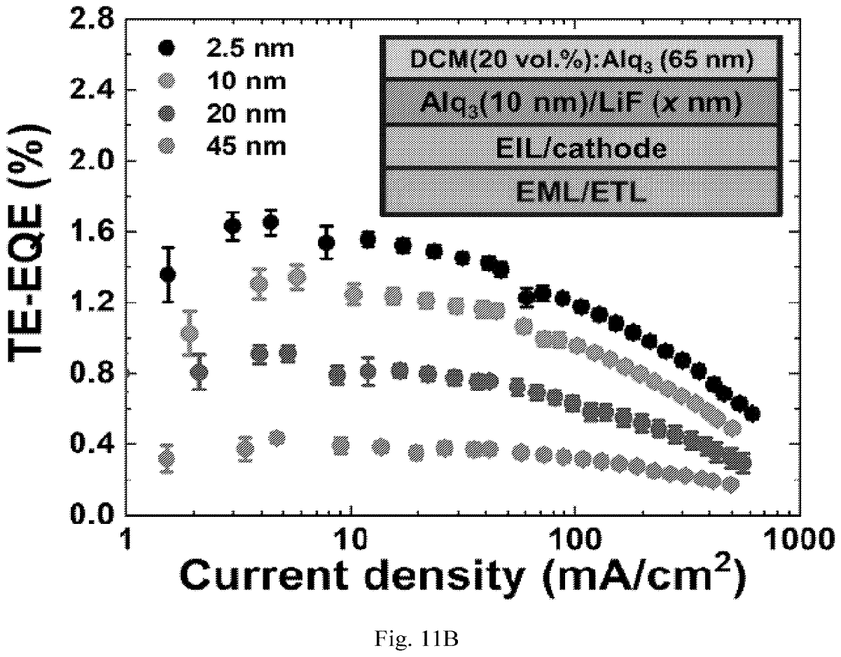

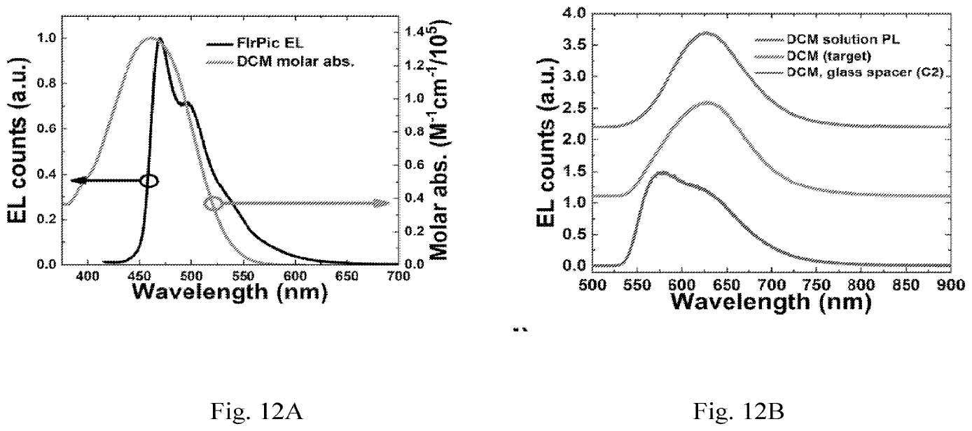

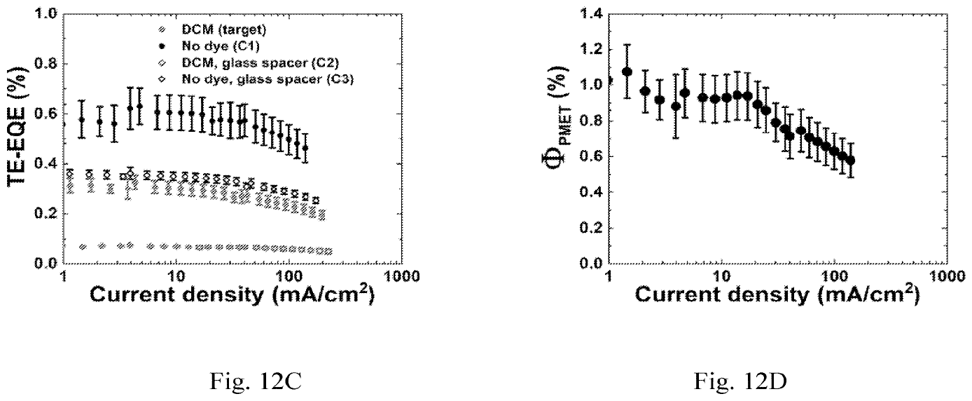

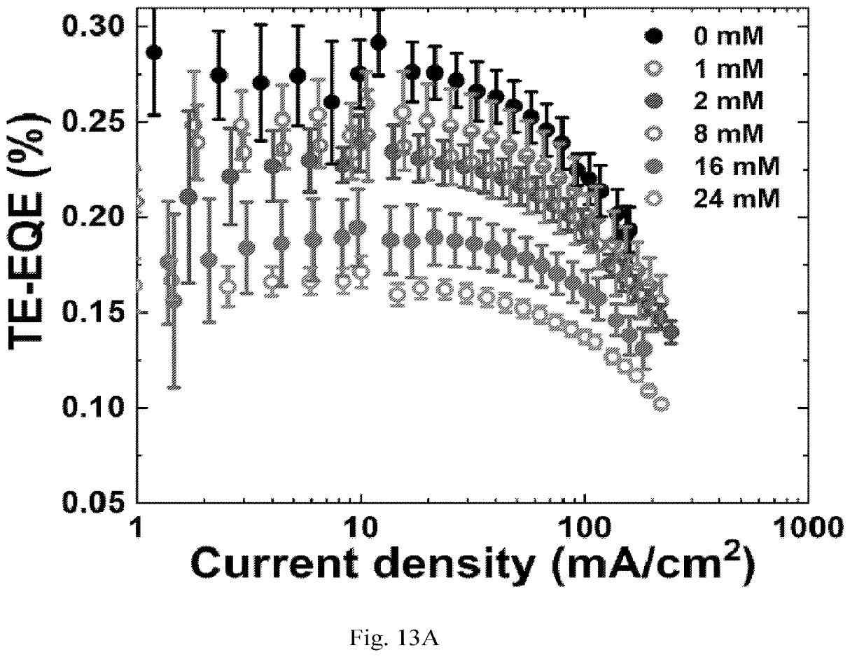

Outcoupling of SPPs-to-acceptor molecules was studied by measuring the top-emitting external quantum efficiency (TE-EQE) of the PMET diode with various thicknesses (2.5, 10, 20, 45 nm) of a low refractive index (n) dielectric (LiF) spacer between the cathode and an emissive acceptor layer. The SPP dispersion relation (see J. R. Sambles, et al., Contemporary Physics, 1991) reveals that lower refractive index dielectric claddings decrease the SPP optical density of states (DOS), thus LiF (n~1.4) was chosen as a dielectric spacer to maximize the spacer-thickness dependence of SPP-to-acceptor coupling. This allows for the use of relatively thin LiF spacer layers and minimizes optical interference effects. A thin-film of the dye 4-(dicyanomethylene)-2-methyl-6-(4-dimethylaminostyryl)-4H-pyran (DCM) doped (20 vol. %) into a tris(8-hydroxyquinoline)aluminum(III) (Alq₃) host was used as the emissive acceptor layer, owing to its broad and intense absorptivity (~1.36×10⁵ M⁻¹ cm⁻¹) that overlaps well with the donor emission (see FIG. 12A). A 10 nm neat Alq₃ layer was included to separate the cathode from LiF to improve wetting. Identical devices without the DCM dye were grown to control for far-field donor photons that escape through the silver cathode. The TE-EQE values from these control devices were subtracted from the DCM:Alq₃ device with identical LiF thickness, thereby isolating DCM emission. All EQE values were calculated assuming a Lambertian angular emission profile. As shown in FIG. 11B, the TE-EQE decreases from 1.65% to 0.44% as the LiF thickness increases from 2.5 to 45 nm. This nm-scale thickness dependence suggests that the DCM emission is near-field mediated.

PMET diode operation was demonstrated with a solution-phase acceptor comprising DCM dye (13 mM) dissolved in acetonitrile (MeCN). The quantum efficiency of the PMET (Φ_{PMET}) to DCM (that is, DCM molecules excited per electron injected) was calculated. It was found that the choice of organic solvent and device materials were crucial in preventing dissolution and delamination of the PMET diode upon submersion. MeCN was chosen as a solvent because it is nonaromatic and highly polar, and is also a commonly-used dye solvent. Other potential solvents include propionitrile, diethylene glycol, dichloromethane. The structural contrast between MeCN and the nonpolar, aromatic small molecules used in the PMET structure discourages dissolution of the diode. To avoid delamination, poly(3,4-ethylenedioxythiophene) polystyrene sulfonate (PEDOT:PSS) was used as a wetting layer for the ITO anode. Solution-processed PEDOT:PSS can smooth rough ITO surfaces, (A. Kohler et al., Wiley, 2015) encouraging more complete films. Furthermore, the silver cathode was capped with 6 nm of Al₂O₃ deposited via atomic layer deposition (ALD) to reduce penetration of MeCN into the device structure. To improve outcoupling to the acceptor, 21 nm of TeO₂(n~2.2) was evaporated on top of Al₂O₃, increasing the SPP optical DOS into MeCN.

To calculate Φ_{PMET}, it is important to note that the solution-phase acceptor layer is limited to a much lower concentration of DCM than the solid-state layer due to the limited solubility of DCM in MeCN (solution phase ~8×10¹⁸ molecules cm⁻³, solid-state ~5×10²⁰ molecules cm⁻³). Since the strength of the SPP-coupling heavily depends on the absorption coefficient of the acceptor layer, the solution phase device is thus limited to a weaker SPP-to-acceptor coupling than the solid-state device. As a result, the QE of DCM emission from PMET is comparable in magnitude to the TE-EQE of donor-emitted far-field photons that escape through the silver cathode.

It is possible to control for the escaping far-field donor photons as well as sub-unity luminescence quantum yield of DCM by using a series of control devices in order to accurately calculate Φ_{PMET}. The first of these control devices (C₁) features neat MeCN as the acceptor layer, revealing the contribution of far-field donor photons to the target device TE-EQE. The neat MeCN preserves a similar optical environment (index of refraction) surrounding the OLED, but without any energy transfer to the solution. Furthermore, both the luminescence quantum yield and the fraction of DCM emission that escapes the device structure is unknown. Thus, a second control device (C₂) was introduced with a macroscopically-thick (150 μm) sheet of coverglass separating the thin-film device from the solution of DCM along with an identical device with neat MeCN (C₃). In both C₂ and C₃, there is no near-field energy transfer due to the many μm-thick coverglass separating the solution and the cathode. Since the 250 μm-thick solution of DCM absorbs ~94% (absorbance calculated by convolving DCM absorptivity with FIrPic EL, see FIG. 12A) of the escaping far-field donor photons, the TE-EQE ratio of C₂ to C₃ is approximately equal to the probability that a DCM exciton will emit a detected photon. By measuring the TE-EQE of the target and the three control devices, it is possible to calculate the Φ_{PMET}:

$${Φ}_{PMET} ≅ {EQE}_{target} ( \frac{{EQE}_{C 3}}{{EQE}_{C 2}} ) - {EQE}_{C 1} \qquad Equation 6$$

In words, Φ_{PMET} is calculated by taking the number of DCM-emitted photons detected in the target device (EQE_{target}), dividing by the probability that a DCM excitation leads to a detected photon (EQE_{C2}/EQE_{C1}), and subtracting the QE contribution of far-field donor photons (EQE_{C1}). The TE-EQEs and calculated Φ_{PMET} are shown in FIG. 12C and FIG. 12D, respectively. A peak Φ_{PMET} of 1.08% was achieved. It should be noted that this expression is a lower bound: roughly 6% of donor emission is not absorbed by DCM due to its broad red tail of emission, and thus the EQE ratio of C₃ to C₂ is artificially inflated. This spectral mismatch can be seen in FIG. 12A, which includes donor electroluminescence (EL) and DCM absorption spectra.

FIG. 12B shows the EL spectra of the C₂ and target devices, along with the photoluminescence (PL) spectrum of a 5 μM DCM in MeCN solution. The target device EL closely resembles the DCM solution PL (628 nm) with a peak located at 626 nm, whereas C₂ has its primary peak at 578 nm and a secondary shoulder at ~628 nm. The 578 nm peak in C₂ may be attributed to the ~6% of far-field donor photons that are not absorbed by the solution. These non-absorbed photons also contribute to the target device EL spectrum; however, because the target device features substantial emission from PMET, the contribution of the non-absorbed photons is minimal. This can be seen from the slight distortion of the EL Gaussian at ~578 nm.

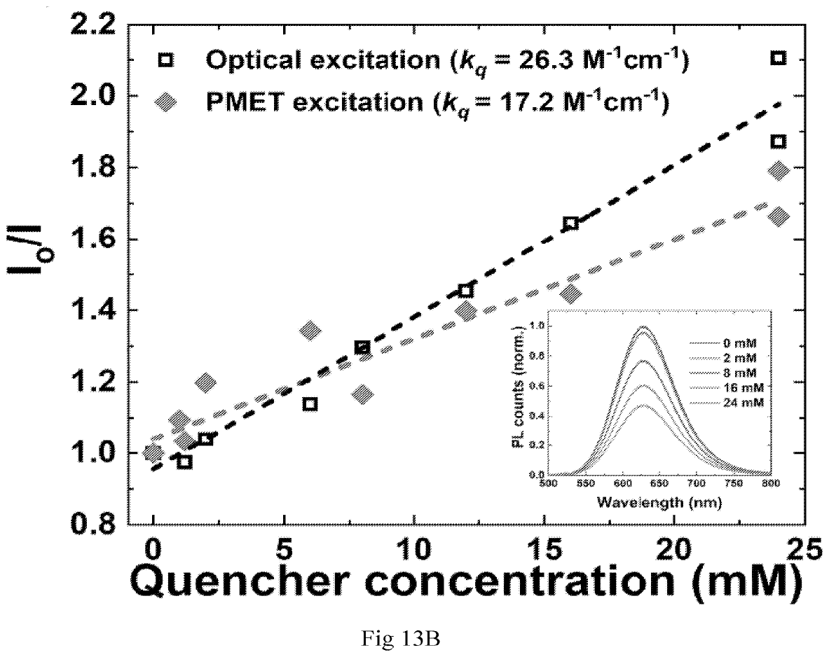

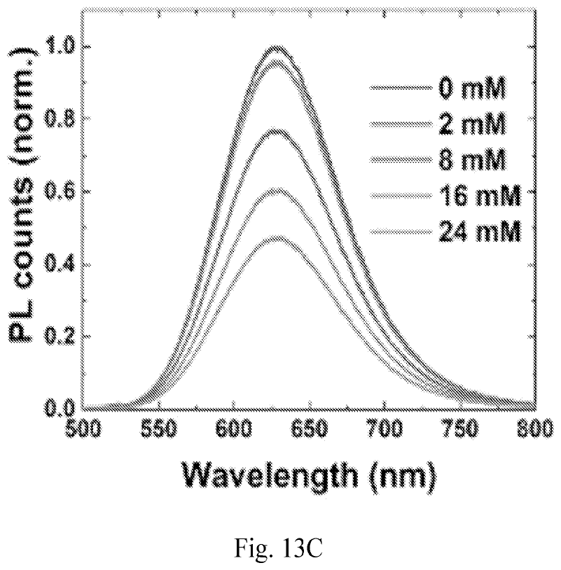

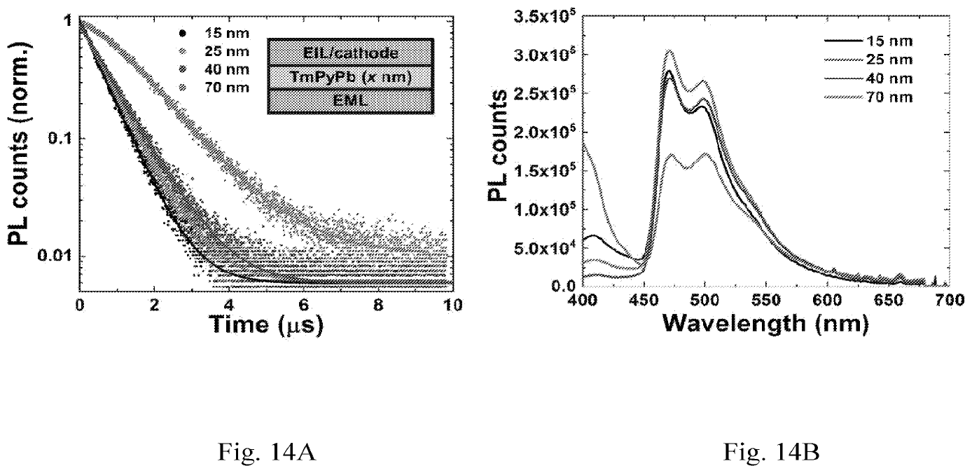

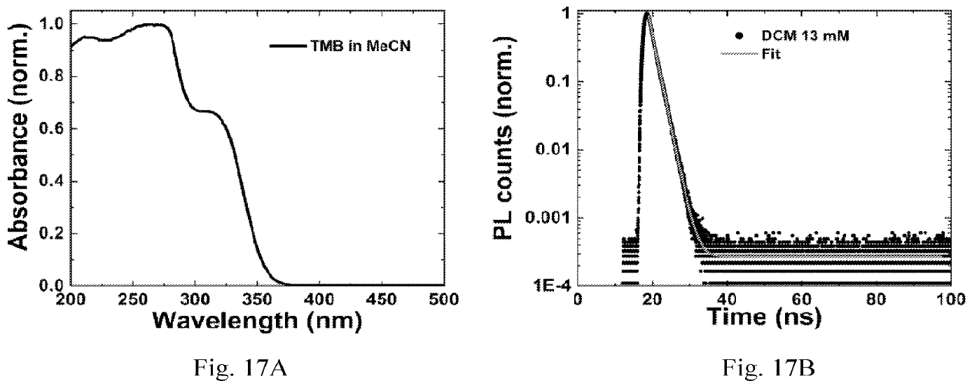

To demonstrate that PMET-excited solution-phase acceptors can participate in a charge transfer reaction, Stern-Volmer luminescence quenching experiments were conducted. The TE-EQE was measured with various concentrations of a strongly electron-donating molecule, N,N,N′,N′-tetramethylbenzidine (TMB) added to the dye solution. FIG. 13A shows the TE-EQE measured from devices with 0, 1, 2, 8, 16, and 24 mM of TMB as a function of current density. As the concentration of TMB increased from 0 to 24 mM, the average TE-EQE from 1-100 mA/cm² decreased from 0.26% to 0.16%. To extract the Stern-Volmer quenching rate k_{q} from this data, the average TE-EQE with no quencher was divided by that of each quenched device, and a linear fit to these points was performed as shown in FIG. 13B. This experiment was repeated with a separate batch of devices and solutions, and these additional points are also included in FIG. 13B. The slope of this linear fit indicates k_{q}×τ_{PL}, where τ_{PL} is the zero-quencher PL lifetime of DCM in MeCN. τ_{PL} was measured (FIG. 17B) of a 13 mM DCM solution to be 1.6 ns. Assuming that τ_{PL} is unchanged between solution and the PMET diode surface, a k_{q} of 17.2×10⁹ M⁻¹ s⁻¹ is obtained. As a comparison, the PL intensity of a photoexcited 13 mM DCM in MeCN solution was measured as a function of TMB concentration, shown in the inset of FIG. 13B and enlarged in FIG. 13C. This control gives a k_{q} of 26.3×10⁹ M⁻¹ s⁻¹.

The decrease in the EL intensity with increasing TMB concentration implies that TMB decreases the luminescence quantum yield of DCM. Because TMB is an electron-rich molecule, it likely donates an electron to excited-state DCM, preventing photon emission. The k_{q} extracted from quenched PMET is a factor of 0.65 lower than the k_{q} from photoexcitation. This reduced k_{q} could be due to Purcell enhancement of the DCM radiative emission rate from coupling to SPP modes, or due to increased collisional quenching with the PMET diode surface.

### DISCUSSION

Design considerations for the PMET diode are disclosed. The Φ_{PMET} defined in Equation 1 can be split into two components: the internal quantum efficiency (IQE) of the OLED (photons created per electron injected), and the outcoupling efficiency to the acceptor layer (acceptor molecules excited per emissive exciton formed). The IQE optimization of the PMET diode and of a display OLED are similar. For example, both devices benefit from including a triplet-harvesting emissive dopant, (C. Adachi, et al., J. Appl. Phys., 2001) designing efficient electrodes, (Y. Zhou, et al., Science, 2012; C. Wu, et al., Appl. Phys. Lett., 1997) or using high carrier mobility transport materials (see S.-J. Su, et al., Adv. Mater., 2008). However, the PMET diode does not require a semitransparent anode, therefore a high-conductivity metal could be used in some embodiments to improve carrier injection. Suitable dopants include, but are not limited to, Flrpic (as used here), Ir(ppy)₃ (as used elsewhere herein), Bis(2,4-difluorophenylpyridinato)-tetrakis(1-pyrazolyl)borate iridium(III) (Fir6), 1,2,3,5-Tetrakis(carbazol-9-yl)-4,6-dicyanobenzene (4CzIPN), or Bis(2-(3,5-dimethylphenyl)quinoline-C2,N′xacetylacetonato)iridium(III) (Ir(dmpq)2(acac)). Suitable transport materials include, but are not limited to, TAPC, TCTA, TpPyPb, TmPyPb (as used elsewhere herein), N,N′-Di(1-naphthyl)-N,N′-diphenyl-(1,1′-biphenyl)-4,4′-diamine (NPB), or B4PymPm. Suitable high conductivity metals include, but are not limited to, silver, copper, aluminum, nickel, chromium, molybdenum, gold, and platinum.

To optimize outcoupling efficiency, in some embodiments, emitters with preferential in-plane dipole orientation should be avoided, (M. C. Gather, et al., Appl. Phys. Lett., 2012) since dipoles that are parallel to metal films couple much more weakly to SPP modes than perpendicularly oriented dipoles. Also, as FIG. 3A suggests, the ETL should be thin in some embodiments. Furthermore, a high-index acceptor layer is desired because the SPP optical DOS increases with the refractive index of the dielectric cladding. However, the refractive index of most organic solvents is in the range of 1.3-1.5 (M. Konstantinos, et al., Appl. Phys. B, 2014). Depositing a thin solid-state high-index film on the cathode can increase the DOS in the low-index solvent. One embodiment of the disclosed device includes a 21 nm TeO₂ (n~2.2) layer.

Moreover, the strength of coupling from SPP modes to acceptor molecules depends heavily on the absorptivity of the acceptor layer, which is the product of the molar absorptivity and the concentration of the acceptor molecule. Intrinsically, SPPs are lossy and thus decay rapidly via thermalization; maximizing the concentration and absorptivity of acceptor molecules increases the likelihood that an SPP will excite an acceptor molecule prior to thermalization. Laser dyes such as DCM, boron-dipyrromethene, fluorescein, and rhodamine are thus excellent photophysical candidates as PMET acceptors due to their high absorptivity (K. H. Drexhage, Springer Berlin, 1990) and solubility.

### CONCLUSION

Disclosed herein is a device that transfers energy from electrically-populated donor excitons to acceptor molecules via surface plasmon polaritons. The working mechanisms of the PMET diode were demonstrated using TRPL and EQE measurements, and showed a 1.08% quantum efficiency for excitation of solution-phase acceptors, and showed that these near-field generated excitons can drive charge transfer reactions. For sensing applications, the PMET diode could excite fluorescent tags without introducing a parasitic excitation signal, which would be more difficult to execute with far-field excitation. Moreover, the disclosed device could enable electrically-driven chemical reactions. This strategy would be well-suited to microscopically-compact photochemical flow reactors, given the nanometer-scale excitation width. The local field enhancement from the SPPs could also be explored for triplet fusion upconversion, which often requires large fields to be enabled.

The disclosures of each and every patent, patent application, and publication cited herein are hereby incorporated herein by reference in their entirety. While this invention has been disclosed with reference to specific embodiments, it is apparent that other embodiments and variations of this invention may be devised by others skilled in the art without departing from the true spirit and scope of the invention. The appended claims are intended to be construed to include all such embodiments and equivalent variations.

### Additional Materials

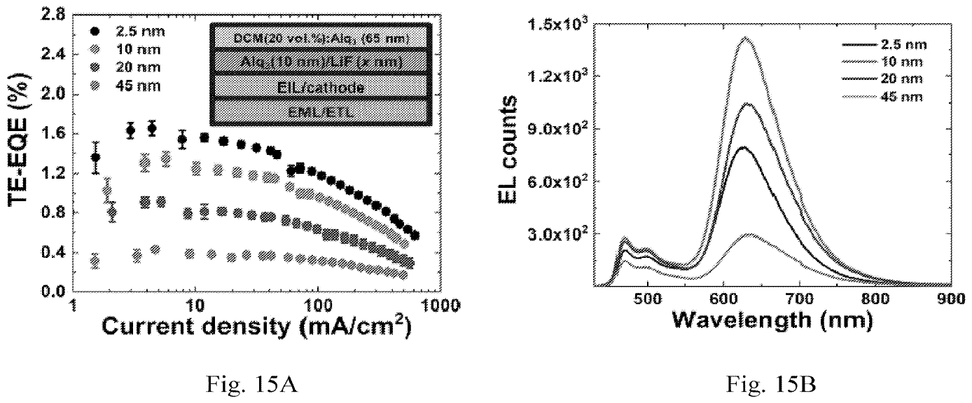

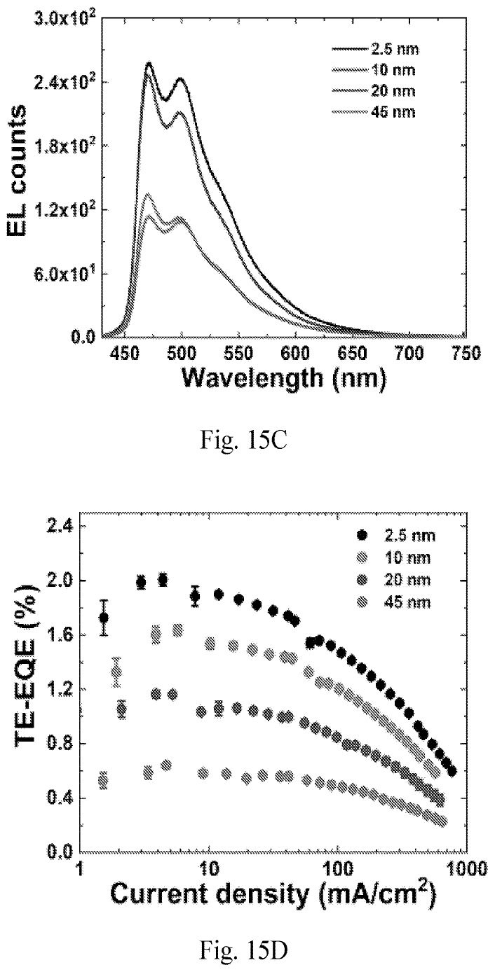

With reference to FIG. 14A and FIG. 14B, FIG. 14A shows TRPL decay curves for structure shown in the inset. As the ETL thickness increases from 15 to 70 nm, monotonic increase in PL lifetime is seen (0.60, 0.70, 0.78, 1.17 μs) attributed to a lessening of the plasmonic radiative decay rate enhancement. TmPyPb thickness is swept from 15 nm to 70 nm. FIG. 14B shows raw steady-state PL spectra from device structures.

All decay curves are fit to a monoexponential decay function. For the 70 nm curve, the monoexponential was fit starting at 2 μs. This is because prior to ~2 μs, there is an unphysically slower rate of decay, which can be explained by absorption of the excitation beam by the FIrPic host materials, and subsequent exciton diffusion and trapping by FIrPic molecules. This assertion is corroborated by FIG. 14B, which shows an increasing contribution of UV emission to the steady state spectra.

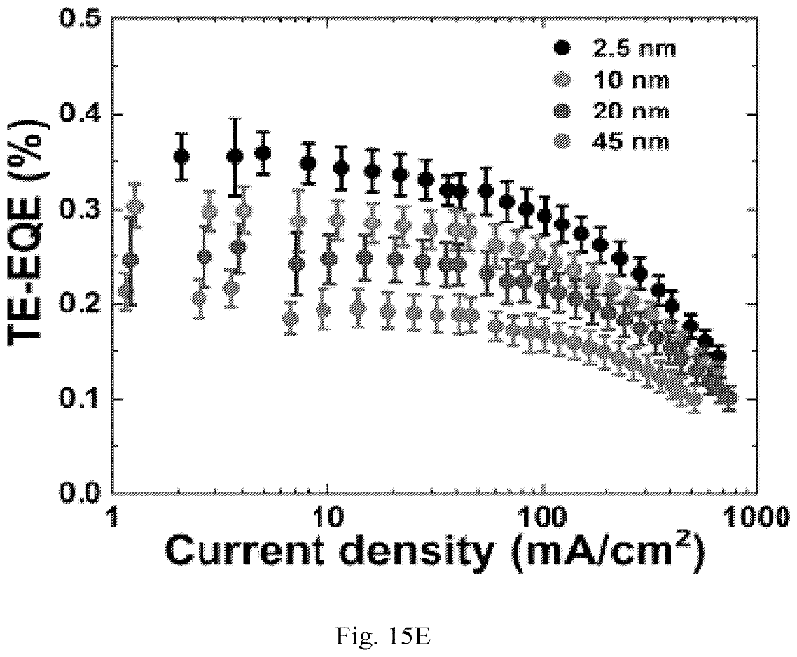

With reference to FIG. 15A, a graph of TE-EQE of DCM emission as a function of current density is shown for the device structure shown in the inset. FIG. 15B Shows the raw EL spectra for all target devices. Features at ~470 nm are attributed to donor emission from EML that escapes through silver cathode, feature at −630 nm attributed to emission of DCM dye. FIG. 15C shows raw EL spectra for all control devices (identical structure to target without DCM dye). All features are attributed to donor emission. FIG. 15D shows top-emitting EQE of target devices. FIG. 15E shows top-emitting EQE of control devices.

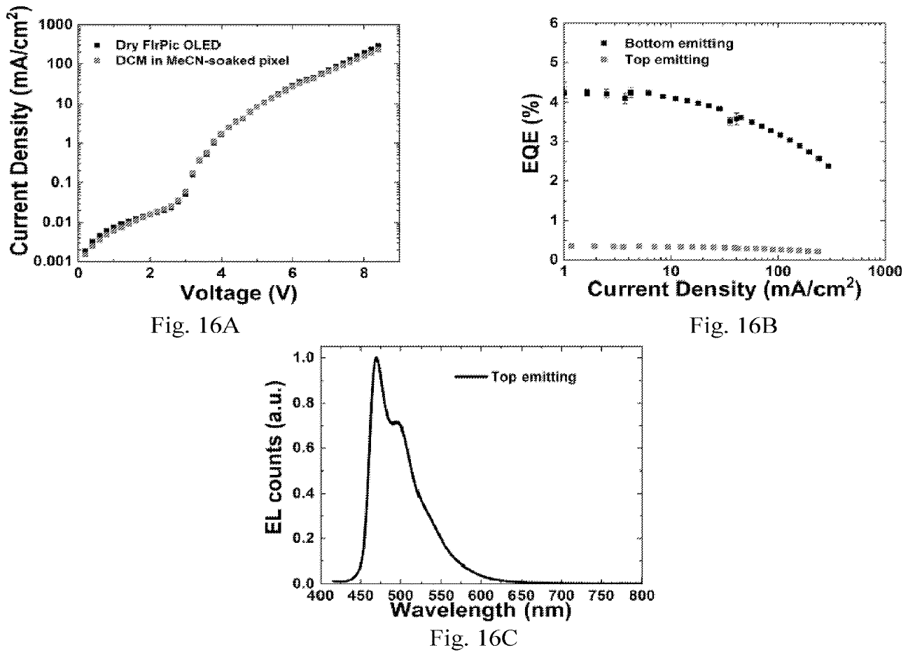

FIG. 16A is a graph of current density versus voltage curves for dry PMET structure and PMET structure submerged in a 13 mM DCM in MeCN solution. FIG. 16B is a graph of bottom emitting and TE-EQE of dry PMET diode. FIG. 16C is a graph of top-emitting EL spectrum of dry PMET diode. FIG. 17A is a graph of normalized UV-vis spectrum of TMB dissolved in MeCN. FIG. 17B shows TRPL of 13 mM DCM solution in MeCN. Monoexponential fit gives a PL lifetime of 1.6 ns.

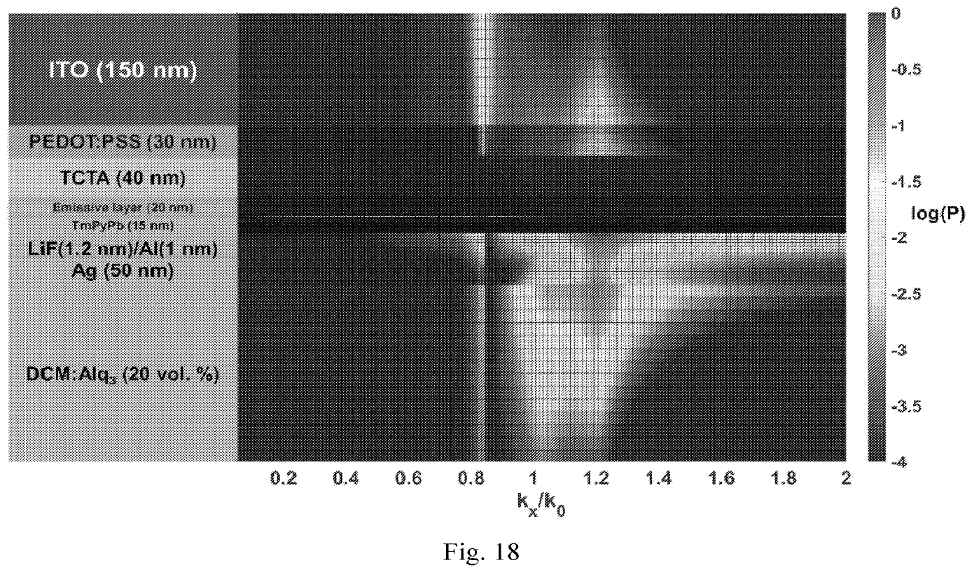

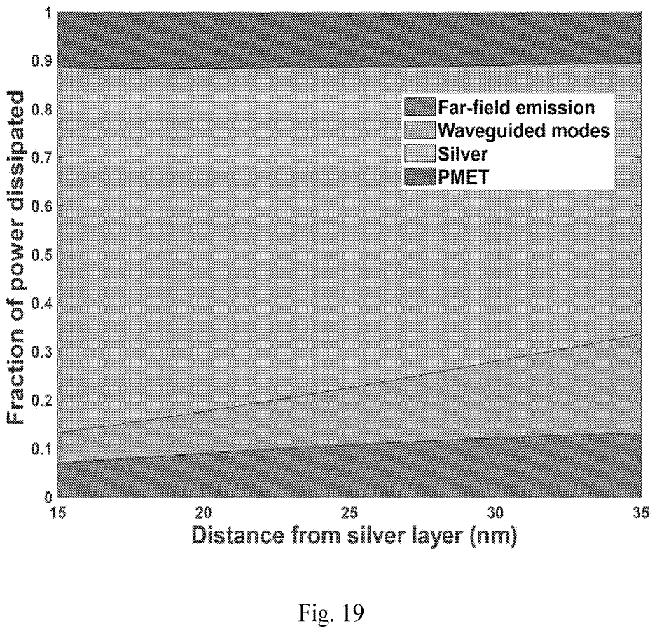

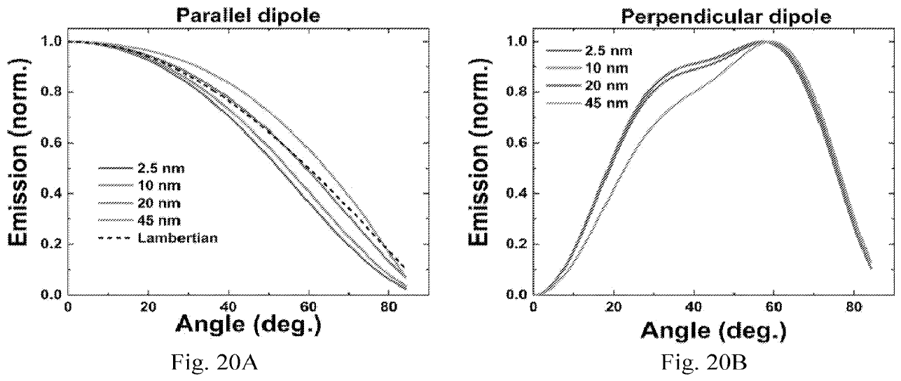

FIG. 18 is a simulated color plot of energy dissipation in the PMET structure as a function of wavevector and vertical position. FIG. 19 is a simulated fraction of total power consumed by each section of device as a function of exciton position within emissive layer. FIG. 20A and FIG. 20B are simulated angular emission profiles of both parallel and perpendicular dipoles emitting from the acceptor layer used in the experiment presented in FIG. 11B.

### REFERENCES

The following publications are incorporated by reference herein in their entireties:
C. W. Tang and S. A. VanSlyke, “Organic electroluminescent diodes,” Applied Physics Letters, vol. 51, no. 12, pp. 913-915, 1987.
M. A. Baldo, F. D. O'Brien, Y. You, A. Shoustikov, S. Sibley, M. E. Thompson and S. R. Forrest, “Highly efficient phosphorescent emission from organic electroluminescent devices,” Nature, vol. 395, no. 6698, pp. 151-154, 1998.
H. Uoyama, K. Goushi, K. Shizu, H. Nomura and C. Adachi, “Highly efficient organic light-emitting diodes from delayed fluorescence,” Nature, vol. 492, no. 7428, pp. 234-238, 2012.
C. K. Prier, D. A. Rankic and D. W. MacMillan, “Visible Light Photoredox Catalysis with Transition Metal Complexes: Applications in Organic Synthesis,” Chemical Reviews, vol. 113, no. 7, pp. 5322-5363, 2013.
J. Kosco, M. Bidwell, H. Cha, T. Martin, C. T. Howells, M. Sachs, D. H. Anjum, S. G. Lopez, L. Zou, A. Wadsworth, W. Zhang, L. Zhang, J. Tellam, R. Sougrat, F. Laquai, D. M. DeLongChamp, J. R. Durrant and I. McCulloch, “Enhanced photocatalytic hydrogen evolution from organic semiconductor heterojunction nanoparticles,” Nature Materials, vol. 19, pp. 559-565, 2020.
L. M. Campos, T. Rovis, D. N. Congreve, E. M. Churchill, A. B. Pun and B. D. Ravetz, “Photoredox catalysis using infrared light via triplet fusion upconversion,” Nature, vol. 565, pp. 343-346, 2019.
T. Terai and T. Nagano, “Small-molecule fluorophores and fluorescent probes for bioimaging,” Pflugers Archiv—European Journal of Physiology, vol. 465, pp. 347-359, 2013.
T. Forster, “Zwischenmolekulare Energiewanderung und Fluoreszenz,” Annalen der Physik, vol. 6, pp. 55-75, 1948.
W. L. Barnes, A. Dereux and T. W. Ebbesen, “Surface plasmon subwavelength optics,” Nature, vol. 424, no. 6950, pp. 824-830, 2003.
P. Andrew and W. L. Barnes, “Energy Transfer Across a Metal Film Mediated by Surface Plasmon Polaritons,” Science, vol. 306, no. 5698, pp. 1002-1005, 2004.
P. A. Hobson, J. A. Wasey, I. Sage and W. L. Barnes, “The role of surface plasmons in organic light-emitting diodes,” IEEE Journal of Selected Topics in Quantum Electronics, vol. 8, no. 2, pp. 378-386, 2002.
P. A. Hobson, S. Wedge, J. A. Wasey, I. Sage and W. L. Barnes, “Surface Plasmon Mediated Emission from Organic Light-Emitting Diodes,” Advanced Materials, vol. 14, no. 19, pp. 1393-1396, 2002.
M. A. Fusella, R. Saramak, R. Bushati, V. M. Menon, M. S. Weaver, N. J. Thompson and J. J. Brown, “Plasmonic enhancement of stability and brightness in organic light-emitting devices,” Nature, vol. 585, pp. 379-382, 2020.
Y. Chen, J. Chen, Y. Zhao and D. Ma, “High efficiency blue phosphorescent organic light-emitting diode based on blend of hole- and electron-transporting materials as a co-host,” Applied Physics Letters, vol. 100, no. 21, 2012.
K. Celebi, T. D. Heidel and M. A. Baldo, “Simplified calculation of dipole energy transport in a multilayer stack using dyadic Green's functions,” Optics Express, vol. 15, no. 4, pp. 1762-1772, 2007.
W. L. Barnes, “Fluorescence near interfaces: The role of photonic mode density” Journal of Modern Optics, vol. 45, no. 4, pp. 661-699, 1998.
J. R. Sambles, G. W. Bradbery and F. Yang, “Optical excitation of surface plasmons: An introduction,” Contemporary Physics, vol. 32, no. 3, pp. 173-183, 1991.
A. Kohler and B. Heinz, Electronic Processes in Organic Semiconductors: An Introduction, Weinheim: Wiley-VCH Verlag GmbH & Co. KGaA, 2015.
C. Adachi, M. A. Baldo, M. E. Thompson and S. R. Forrest, “Nearly 100% internal phosphorescence efficiency in an organic light-emitting device,” Journal of Applied Physics, vol. 90, no. 10, pp. 5048-5051, 2001.
Y. Zhou, C. Fuentes-Hernandez, J. Shim, J. Meyer, A. J. Giordano, H. Li, P. Winget, T. Papdopoulos, H. Cheun, J. Kim, M. Fenoll, A. Dindar, W. Haske, E. Najafabadi, T. M. Khan, H. Sojoudi, S. Barlow, S. Graham, J.-l. Bredas, S. R. Marder, A. Kahn and B. Kippelen, “A Universal Method to Produce Low-Work Function Electrodes for Organic Electronics,” Science, vol. 336, no. 6079, pp. 327-332, 2012.
C. Wu, C. Wu, J. C. Sturm and A. Kahn, “Surface modification of indium tin oixde by plasma treatment: An effective method to improve the efficiency, brightness, and reliability of organic light emitting devices,” Applied Physics Letters, vol. 70, no. 1348, 1997.
S.-J. Su, T. Chiba, T. Takeda and J. Kido, “Pyridine-Containing Triphenylbenzene Derivatives with High Electron Mobility for Highly Efficient Phosphorescent OLEDs,” Advanced Materials, vol. 20, no. 11, pp. 2125-2130, 2008.
M. C. Gather, K. Leo, B. Lussem, M. Furno, C. Murawski and P. Liehm, “Comparing the emissive dipole orientation of two similar phosphorescent green emitter molecules in highly efficient organic light-emitting diodes,” Applied Physics Letters, vol. 101, no. 253304, 2012.
M. Konstantinos, M. Papamichael, S. C. Betsis, I. Stavrakas, G. Hloupis and D. Triantis, “Refractive, dispersive and thermo-optic properties of twelve organic solvents in the visible and near-infrared,” Applied Physics B, vol. 116, pp. 617-622, 2014.
K. H. Drexhage, “Structure and properties of laser dyes,” in Dye Lasers, Heidelberg, Springer Berlin, 1990, pp. 155-200.

1-28. (canceled)

29. A device, comprising:
an emissive donor layer disposed between a first electrode and a first surface of a second electrode; and
an acceptor layer operably coupled to a second surface of the second electrode, the second surface being opposite the first surface.

30-31. (canceled)

32. The device according to claim 29, further comprising at least one electron injection layer (EIL) and/or hole injection layer (HIL) between the first electrode and the emissive donor layer.

33. The device according to claim 29, wherein the device includes an EIL and an HI.

34-37. (canceled)

38. The device according to claim 29, further comprising a charge transport layer positioned between the emissive layer and the second electrode, and a dielectric spacer layer between the charge transport layer and the second electrode, wherein the dielectric spacer layer has a reflective index less than 1.5.

39-40. (canceled)

41. The device according to claim 29, further comprising a second dielectric layer between the second electrode and the acceptor layer, wherein the second dielectric layer has a refractive index less than 1.5.

42-44. (canceled)

45. The device according to claim 29, wherein the acceptor layer comprises a solid-state acceptor with a bandwidth that overlaps an emission bandwidth of the emissive donor layer.

46-50. (canceled)

51. The device of claim 29, further comprising:
a first charge transport layer positioned between the first electrode and the emissive donor layer;
a second charge transport layer positioned between emissive donor layer and the second electrode;
wherein the acceptor layer is an organic emissive layer positioned over the second electrode, configured to convert surface plasmon polaritons on a surface of the second electrode to light.

52. The device of claim 51, wherein the wherein the acceptor layer comprises a solution-phase or solid state acceptor material, an upconversion layer, 2-methyl-9,10-bis(naphthalen-2-yl)anthracene (MADN), a phosphorescent emitter, delayed fluorescent emitter, or a non-delayed fluorescent emitter.

53. The device of claim 51, wherein the acceptor layer or the emissive donor layer comprises a sensitizer and an acceptor.

54. The device of claim 51, wherein the emissive donor layer comprises a material selected from a phosphorescent emitter, delayed fluorescent emitter, and a non-delayed fluorescent emitter, a green emissive layer, a blue emissive layer, a yellow emissive layer, a red emissive layer, a near IR emissive layer, a metal compound selected from Ir, Pt, Pd, Os, Cu, Ag, or Au.

55. The device of claim 51, wherein the emissive donor layer comprises a triplet-harvesting emissive dopant.

56. The device of claim 51, further comprising a second emissive layer positioned between the first charge transport layer and the emissive donor layer, wherein the second emissive layer has a thickness of less than 3 nm.

57. A consumer product comprising the device of claim 29, wherein the consumer product is selected from the group consisting of a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video walls comprising multiple displays tiled together, a theater or stadium screen, a light therapy device, and a sign.

58. The device of claim 29, further comprising:
a first charge transport layer positioned between the first electrode and the emissive donor layer;
a second emissive layer positioned between the emissive donor layer and the second electrode; and
a second charge transport layer positioned between the second emissive layer and the second electrode;
wherein the acceptor layer is a blue upconversion layer configured to convert surface plasmon polaritons on a surface of the second electrode to blue light.

59. The device of claim 58, wherein the emissive donor layer and the second emissive layer are selected from a red emissive layer or a green emissive layer.

60. The device of claim 58, wherein the emissive donor layer has a thickness of less than 3 nm.

61. The device of claim 58, wherein the blue upconversion layer comprises a sensitizer layer and an annihilator layer.

62. The device of claim 58, further comprising a power source configured to drive the device at a current density of at least 100 mA/cm².

63. The device of claim 29, wherein the second electrode comprises an enhancement layer and wherein the emissive donor comprises an organic emissive material; and wherein the enhancement layer comprises a plasmonic material exhibiting surface plasmon resonance that non-radiatively couples to the organic emissive material and transfer excited state energy from the organic emissive material to non-radiative mode of surface plasmon polaritons.

64. The device of claim 63, wherein the enhancement layer is provided no more than a threshold distance away from the organic emissive layer,
wherein the organic emissive material has a total non-radiative decay rate constant and a total radiative decay rate constant due to the presence of the enhancement layer, and the threshold distance is where the total non-radiative decay rate constant is equal to the total radiative decay rate constant.
